(19) United States
(12) Patent Application Publication
(10) Pub. No.: US 2023/0125793 A1
(43) Pub. Date: Apr. 27, 2023

(54) METHOD OF MAKING HEXAGONAL BORON NITRIDE COATINGS AND COMPOSITIONS AND METHODS OF USING SAME

(71) Applicant: William Marsh Rice University, Houston, TX (US)

(72) Inventors: Jun Lou, Houston, TX (US); Qilin Li, Houston, TX (US); Weipeng Wang, Houston, TX (US); Kuichang Zuo, Houston, TX (US); Shuai Jia, Houston, TX (US); Weibing Chen, Houston, TX (US)

(73) Assignee: WILLIAM MARSH RICE UNIVERSITY, Houston, TX (US)

(21) Appl. No.: 17/974,297

(22) Filed: Oct. 26, 2022

Related U.S. Application Data
(60) Provisional application No. 63/272,010, filed on Oct. 26, 2021.

(51) Int. Cl. C23C 16/34; C23C 16/02; C23C 16/448; C23C 16/455; C23C 16/46

(52) U.S. Cl. CPC C23C 16/342; C23C 16/0227; C23C 16/4481; C23C 16/45557; C23C 16/463

(57) ABSTRACT

Methods of making hexagonal boron nitride coatings upon stainless steel and other ferrous metal/alloy materials, compositions thereof, and methods of using same, such as in electrothermal membrane distillation systems using hexagonal boron nitride coated metal mesh.

### CROSS-REFERENCE TO RELATED PATENT APPLICATIONS

This application claims priority to U.S. patent application Ser. No. 63/272,010, filed Oct. 26, 2021, entitled “Method Of Making Hexagonal Boron Nitride Coatings And Compositions And Methods Of Using Same,” which application is commonly owned by the owner of the present invention and is incorporated herein in its entirety (including appendices).

### STATEMENT REGARDING FEDERALLY SPONSORED RESEARCH

This invention was made with government support under Grant No. EEC-1449500 and Grant No. IIP-1539999 awarded by the National Science Foundation. The government has certain rights in the invention.

### TECHNICAL FIELD

The present invention relates to methods of making hexagonal boron nitride coatings and compositions and methods of using same, and more particularly, methods of making hexagonal boron nitride coatings upon stainless steel and other ferrous metal/alloy materials, compositions thereof, and methods of using same, such as in electrothermal membrane distillation systems using hexagonal boron nitride coated metal mesh.

### BACKGROUND

Corrosion of functional and structural components in industry will significantly reduce their working efficiency and increase maintenance cost. [Dwivedi 2017]. It accounts for more than half of failure cases in the world and costs tens of billion dollars every year. [Panossian 2012; Finšgar 2014; Walsh 2017]. In addition, the industry also has increasing demands on further developing existing coating technologies for harsher working conditions, such as high temperature, high pressure, and highly-corrosive environments. Therefore, new coating solutions are highly desirable to solve many tough practical problems and potentially lower associated enormous economic losses.

Owing to the unique layered structure, large bandgap, and high dielectric constant, hexagonal boron nitride (h-BN) has been a star member of the 2D materials family and has been widely studied as atomically smooth substrate for high-performance electronic and optoelectronic devices and as thin dielectric layers for vertical tunneling devices. [Kim 2015; Chandni 2015; Britnell 2012; Liu I 2013; Lu 2015; Lu 2017; Withers 2015; Tang 2015; Kim 2012; Fu 2016]. Previous studies have demonstrated that ultrathin h-BN also exhibits excellent chemical innerness and thermal stability. [Liu II 2013; Li 2014; Mahvash 2017; Husain 2013; Zhang J 2016; Avsar 2015; Yan 2014; Kostoglou 2015; Upadhyayula 2018; Zuo 2020]. It is stable in air at high temperature up to 1,100° C. [Liu II 2013], and is also stable under extreme conditions where the substrates would undergo violent chemical reactions. These traits make h-BN a promising material for protective coatings for a myriad of industry applications, if high quality and large-area continuous h-BN films could be fabricated directly on industry relevant substrates, such as stainless-steel plates and tubes.

Previously, pure copper, nickel, and their alloys were widely used as substrates to grow monolayer or few-layers h-BN. [Kim 2015; Lu 2015; Tay 2014]. Liu II 2013 found CVD-grown h-BN films on nickel could serve as an oxidation-resistant coating at high temperature in air. However, most of the functional and structural parts used in industry, such as downhole tools, are mostly made of steels or other ferrous alloys. Previously, h-BN atomically thin films grown on copper or nickel substrates were transferred to other metal substrates as protective coatings. [Zhang J 2016; Avsar 2015]. However, the complicated transfer process from copper or nickel substrates to steel-based substrates apparently becomes the hurdle to practical industry applications.

In addition, even the growth of high-quality and large-area 2D materials, such as graphene and transition-metal dichalcogenides (TMDs), has been successfully realized by CVD method recently [Hao 2013; Kang 2015; Zhang 2017; Najmaei 2013; Jia 2016], it is still challenging to grow high quality 2D materials on industry relevant substrates with complicate phases and compositions. More importantly, it is easy to scratch or create pinholes in monolayer or few layers h-BN coating accidently during the fabrication process in industry applications. Finally, active ions or molecules may still diffuse into underlying substrates and corrode substrates via intrinsic defects in the h-BN coatings, such as grain boundaries. The short diffusion path of active ions or molecules in monolayer or few layers h-BN coatings will increase the corrosion rate and shorten the lifetime of functional components.

Accordingly, needs remain for a method of making hexagonal boron nitride coatings upon stainless steel and other ferrous metal/alloy materials Indeed, there is a need for hexagonal boron nitride coated substrates for a variety of uses. This invention was funded in part by the Robert A. Welch Foundation under Welch Grant No. C-1716.

### SUMMARY OF THE INVENTION

The present invention relates to an effective CVD method of growing high quality, uniform, and large-area continuous h-BN thin films on stainless-steel substrates (or substrates of other ferrous metal/alloy materials) directly to protect the substrate from oxidization and corrosion. The h-BN thin films can be grown on flat surfaces as well as curved surfaces (such as tubes), through a low-pressure chemical vapor deposition (LPCVD) method. At high temperature and in a reductive atmosphere, precursors were catalyzed, decomposed, and deposited onto stainless-steel (and other ferrous metal/alloy materials) surfaces to form small h-BN crystalline triangles. These triangles subsequently merged together to form large-area and continuous films.

Such hexagonal boron nitride coated substrates can be used in a variety of uses. Thus, the present invention further can be used in applications such as a multifunctional nanocoated membrane for high-rate electrothermal desalination of hypersaline waters.

In general, in one embodiment, the invention features a method that includes selecting substrate that is a ferrous metal or ferrous alloy substrate. The method further includes utilizing a low-pressure chemical vapor deposition to continuously grow a hexagonal boron nitride film upon the substrate to form a hexagonal boron nitride coated substrate.

Implementations of the invention can include one or more of the following features:

The substrate can be a stainless steel substrate.

The substrate can be a microporous stainless steel wire cloth.

The substrate can be cleaned before the step of utilizing the low-pressure chemical vapor deposition.

The substrate can be cleaned to remove surface oxide.

The substrate can be cleaned with HCl.

The HCl can be diluted HCl.

A precursor can be utilized during the low-pressure chemical vapor deposition.

The precursor can be selected from the group consisting of (a) ammonia borane, (b) NH₃ and diborane, and (c) combinations thereof.

The precursor can be ammonia borane.

The precursor can be NH₃ and diborane.

A carrier gas can be utilized during the low-pressure chemical vapor deposition.

The carrier gas can include a gas selected from the group consisting of hydrogen, Ar, He, and combinations thereof.

The carrier gas can include hydrogen.

The carrier gas can include Ar.

The carrier gas can include He.

The carrier gas can be flowed during the low-pressure chemical vapor deposition at a rate in a range of 50 sccm and 500 sccm.

The low-pressure chemical vapor deposition can performed at a pressure in a range of 0.01 Torr and 0.5 Torr.

The method can include utilizing a temperature of greater than 1,000° C. to grow the hexagonal boron nitride film.

The method can include ramping temperature from a first temperature below 1,000° C. to a second temperature of at least 1,000° C. over a first period of time.

The method can further include maintaining the temperature at the second temperature for a second period of time to grow the hexagonal boron nitride film.

The method further can further include cooling the temperature to a third temperature below 1,000° C.

The first temperature and the third temperature can be room temperature.

The second temperature can be at least 1,100° C.

The step of ramping the temperature from the first temperature to the second temperature can include ramping the temperature from the first temperature to an interim temperature over a first portion of the first period. The step of ramping the temperature from the first temperature to the second temperature can further include ramping the temperature from the interim temperature to the second temperature over a second portion of the first period.

The interim temperature can be at least 1,000° C. The second temperature can be at least 1,100° C.

The ramping the temperature from the first temperature to an interim temperature can be at a first linear rate. The ramping the temperature from the first temperature to an interim temperature can be at a second linear rate. The first linear rate can be greater than the second linear rate.

The first portion of the first period can be for at least 30 minutes. The second portion of the first period can be for at least 20 minutes. The second period can be for at least 5 minutes. The cooling to the third temperature can be performed by allowing the temperature to cool down naturally to room temperature.

The first portion of the first period can be at most 60 minutes. The second portion of the first period can be for at most 60 minutes. The second period can be for at most 20 minutes.

The hexagonal boron nitride film can have a thickness less than 500 nm.

The hexagonal boron nitride film can have a thickness less than 250 nm.

The step of utilizing the low-pressure chemical vapor deposition can include positioning the substrate in a furnace and utilizing the furnace during the step of utilizing the low-pressure chemical vapor deposition.

In general, in another embodiment, the invention features a coated substrate that includes a substrate comprising stainless steel, and a continuous hexagonal boron nitride film coating the substrate.

Implementations of the invention can include one or more of the following features:

The substrate can be a microporous stainless steel wire cloth.

The coated substrate can be made by one or more any of the above-described methods.

The coated substrate can be a membrane.

The membrane can be operable for use in an electrothermal membrane distillation system.

The membrane can be operable to be the surface electro-heating element of the electrothermal membrane distillation system.

The membrane can be operable in the electrothermal membrane distillation system at household frequency.

The membrane can have a spiral wound configuration.

The membrane can be operable for use in a surface heating membrane distillation system.

The continuous hexagonal boron nitride film can have a thickness less than 500 nm.

The continuous hexagonal boron nitride film can have a thickness less than 250 nm.

In general, in another embodiment, the invention features a method that includes selecting one or more of any of the above-described coated substrates. The method further includes utilizing the coated substrate as a surface electro-heating element of an electrothermal membrane distillation system.

In general, in another embodiment, the invention features an electrothermal membrane distillation system that includes a microporous membrane comprising stainless steel. The stainless steel is coated with a continuous hexagonal boron nitride film.

Implementations of the invention can include one or more of the following features:

The microporous membrane is the surface electro-heating element of the electrothermal membrane distillation system.

The electrothermal membrane distillation system can operate the membrane at household frequency.

The membrane can have a spiral wound configuration.

The continuous hexagonal boron nitride film can have a thickness less than 500 nm.

The continuous hexagonal boron nitride film can have a thickness less than 250 nm.

In general, in another embodiment, the invention features a coated substrate that includes a substrate that includes a ferrous metal or ferrous alloy, and a continuous hexagonal boron nitride film coating the substrate.

Implementations of the invention can include one or more of the following features:

The coated substrate can be made by one or more of any of the above-described methods.

The coated substrate can be a membrane.

The membrane can be operable for use in an electrothermal membrane distillation system.

The membrane can be operable to be the surface electro-heating element of the electrothermal membrane distillation system.

The continuous hexagonal boron nitride film coating can provide to the substrate a characteristic selected from the group consisting of heat conduction, electric insulation, anti-scaling, anti-bacterial, physical protection against corrosion, physical protection against oxidation, and combinations thereof.

The continuous hexagonal boron nitride film coating can be operable to provide to the substrate the characteristic for the use under extreme conditions.

The extreme conditions can be selected from the group consisting of high temperature, high electrical voltage, harsh chemicals, and combinations thereof.

The harsh chemicals include a strong acid or strong base.

In general, in another embodiment, the invention features a method that includes selecting one or more of any of the above-described coated substrates. The method further includes utilizing the coated substrate as a surface electro-heating element of an electrothermal membrane distillation system.

In general, in another embodiment, the invention features an electrothermal membrane distillation system including a microporous membrane that includes ferrous metal or ferrous alloy. The ferrous metal or ferrous alloy is coated with a continuous hexagonal boron nitride film.

Implementations of the invention can include one or more of the following features:

The microporous membrane can be the surface electro-heating element of the electrothermal membrane distillation system.

In general, in another embodiment, the invention features a method that includes selecting one or more of any of the above-described coated substrates. The method further includes utilizing the coated substrate in a system. The continuous hexagonal boron nitride film coating provides to the substrate a characteristic selected from the group consisting of heat conduction, electric insulation, anti-scaling, anti-bacterial, physical protection against corrosion, physical protection against oxidation, and combinations thereof.

Implementations of the invention can include one or more of the following features:

The coated substrate can be utilized in the system under extreme conditions.

The extreme conditions can be selected from the group consisting of high temperature, high electrical voltage, harsh chemicals, and combinations thereof.

In general, in another embodiment, the invention features a system that includes one or more of any of the above-described coated substrates. The continuous hexagonal boron nitride film coating provides to the substrate in the system a characteristic selected from the group consisting of heat conduction, electric insulation, anti-scaling, anti-bacterial, physical protection against corrosion, physical protection against oxidation, and combinations thereof.

In general, in another embodiment, the invention features a method of direct making of high quality, uniform, and large-area continuous h-BN film on stainless steel plates as an anti-corrosion coating.

### BRIEF DESCRIPTION OF THE DRAWINGS

FIGS. 1A-1F show h-BN thin films grown directly on a stainless-steel substrate. FIGS. 1A-1B are SEM images of h-BN thin films. Many triangular h-BN flakes merge together to form continuous films. Inset is the optical image of stainless-steel substrate before and after h-BN growth. The edge length of the sample is about 10 mm. FIG. 1C is a TEM image of h-BN thin films. Inset is its diffraction pattern. FIG. 1D is a XRD spectra of h-BN thin films on stainless-steel substrate. FIG. 1E is a Raman spectra of −BN thin films on stainless-steel substrate. FIG. 1F is a XPS spectra of B and N element in h-BN thin films on stainless-steel substrate.

FIG. 2A-2B show, respectively, the top-side and bottom-side of stainless-steel after h-BN growth. h-BN could uniformly grow on both sides and they exhibit the same color contrast, illustrating their thickness are almost the same. The edge length of the sample is about 10 mm.

FIG. 3A shows optical images of a stainless-steel tube before and after h-BN growth. h-BN also can grow on curved surface. The tube diameter is ¼ inch.

FIG. 3B is Raman spectra of h-BN on stainless-steel tubes.

FIGS. 4A-4B show XRD mapping of h-BN thin films on stainless-steel substrate. h-BN film was divided into six regions (FIG. 4A), and each region revealed almost identical (002) peak intensity (FIG. 4B), illustrating h-BN film on stainless-steel are uniform.

FIGS. 5A-5H show h-BN growth process on stainless-steel substrate. FIGS. 5A-5E are SEM images of h-BN town on stainless-steel substrate with growth period of 1 min, 2 min, 5 min, 10 min, and 15 min. The scale bar is 5 μm. Insets are the corresponding optical images of h-BN grown on stainless-steel substrate. The edge length of each substrate is about 10 mm. FIG. 5F is the cross-section SEM image of continuous h-BN thin films grown on stainless-steel substrate. The h-BN thin film thickness is estimated to be around 220 nm. FIG. 5G shows relationship of h-BN coverage on stainless-steel substrate as a function of growth time. The dashed line shows the fitting curve according to Lagergren pseudo first-order model. FIG. 5H is XPS relative atomic elemental concentration of each element versus sputtering cycles.

FIGS. 6A-6B are SEM images of bare stainless-steel at room temperature and heated in the air at 800° C. for 1 h. Plenty of triangular prisms appeared on the surface after heating in the air. Inset is the zoom-in image of the triangular prisms. The scale bar is 5 μm.

FIG. 6C is Raman spectra of bare stainless steer before and after oxidization.

FIGS. 6D-6E are SEM images of h-BN coated stainless steel at room temperature and heated in the air at 800° C. for 1 h. The scale bar is 5 μm.

FIG. 6F is Raman spectra of h-BN-coated stainless steel before and after oxidization.

FIGS. 7A(i)-7A(iv) and 7B(i)-7B(iv) show anti-oxidization performance of h-BN coating. FIGS. 7A(i)-7A(iv) are white-balanced optical images of stainless-steel heated in the air for 1 hour at 25° C., 600° C., 700° C.,800° C., respectively. FIGS. 7B(i)-7B(iv) are white-balanced optical images of h-BN coated stainless-steel heated in the air for 1 hour at 25° C., 600° C., 700° C., 800° C., respectively. The scale bar is 10 μm.

FIGS. 8A-8B show anti-corrosion performance of h-BN coating. FIG. 8A are Tafel curves of bare stainless steel and h-B/stainless steel in 1 M HCl solution at room temperature. FIG. 8B are Tafel curves of bare stainless steel and h-BN/stainless steel in 0.1 M HCl solution at 120° C. Intersection of the dash lines indicates the corrosion current density.

FIG. 9 shows electrochemical impedance of bare stainless-steel and h-BN coated stainless-steel in 1 M HCl solution at room temperature.

FIGS. 10A-10B are Optical images of h-BN coated stainless-steel before and after elevated temperature corrosion test. The scale bar is 5 mm.

FIGS. 10C-10D are Optical images of bare stainless-steel before and after high temperature corrosion test. The scale bar is 5 mm.

FIGS. 11A, 11B(i)-11B(ii), and 11C show hexagonal boron nitride as a multifunctional coating on SSWC in electrothermal SHMD. FIG. 11A shows direct surface heating at the membrane-brine interface maintains the transmembrane temperature gradient along the membrane length, and it reverses the temperature polarization on the feed side. T_{f}, Tₚ, T_{f}′, Tₚ′ are the temperature of feed and permeate at the inlet and outlet of the SHMD reactor, respectively. \tilde{V} is the applied voltage. FIG. 11B(i) shows finite-difference heat and mass transfer modelling demonstrates an extraordinary and sustained increase in the average water flux with surface heat input and normalized membrane area in an SHMD membrane module. R, water recovery ratio; M_{Fjn}inlet mass flow rate of the feed stream; Aₘ, membrane area. Shading represents the impact of increasing the minimum temperature difference in an external heat exchanger from 0° C. (solid curve, upper edge of each curve) to 5° C. (lower edge) for a given normalized membrane area. The feed salinity is 70 g kg⁻¹ and the membrane permeability coefficient is 5.0×10⁻⁶ kg m⁻² s⁻¹ Pa⁻¹ (1,800 kg m⁻² h⁻¹ bar⁻¹) throughout. FIG. 11B(ii) shows SEC as a function of the surface heat input for a single plate-and-frame SHMD membrane module (inset) with heat recovery efficiencies of 80%, 90% and 95%. The membrane permeability coefficient decreases from 4.0×10⁻⁶ kg m⁻² s⁻¹ Pa⁻¹ (1,440 kg m⁻² h⁻¹ bar⁻¹) at the lower edge of each curve to 1.0×10⁻⁶ kg m⁻² s⁻¹ Pa⁻¹ (360 kg m⁻² h⁻¹ bar⁻¹) at the upper edge. The feed salinity is 70 g kg⁻¹ and the normalized membrane area is 4.0×10⁻³ m² kg⁻¹ h throughout. FIG. 11C shows The metal mesh structure enables efficient Joule heating and spatial distribution of heat, with the hBN-SSWC shell-core structure allowing efficient heat exchange while blocking any exchange of charge or mass.

FIGS. 12A-12H show growth of high-quality h-BN nanocoatings on SSWC. FIG. 12A is a SEM image of hBN-SSWC with the inset showing the photographs of pristine and hBN-coated SSWC. FIG. 12B is Raman spectrum of hBN-SSWC with the inset showing the FWHM. FIG. 12C is XPS spectrum of hBN-SSWC with fitted peaks of B1s (188.9 eV) and N1s (396.4 eV) with the insets showing the Gaussian fitted peaks of B1s (left) and N1s (right). FIG. 12D is cross-sectional TEM images of hBN-SSWC at various magnifications. FIG. 12E is atomic-resolution TEM of the h-BN layers shows interlayer spacing of ˜3.6 Å with the inset showing the selected area diffraction pattern. FIG. 12F is high-angle annular dark-field imaging (HAADF) and elemental maps of the sectional view of hBN-SSWC. FIG. 12G is the h-BN nanocoating endows an excellent charge-insulating property in the cross direction, even under a test voltage between −20 and +20 V (inset). FIG. 12H is electrochemical impedance spectroscopy data of hBN-SSWC at various salt concentrations. Z′ and −Z″ represent the real and imaginary part of the impedance, respectively.

FIGS. 13A-13F show the hBN-SSWC supports high-energy input in SHMD to realize high performance. FIG. 13A is a schematic of the electrothermal SHMD experimental system. Tem, temperature sensor; Cond, conductivity sensor; PC, personal computer; \tilde{V}, applied voltage. FIG. 13B is current production by pristine SSWC and hBN-coated SSWC. FIG. 13C is membrane flux at various power densities; inset shows the nonlinear relationship between flux and energy intensity (EI). FIG. 13D is effluent salt concentration of the feed and permeate in hBN-SSWC SHMD. FIG. 13E is HUEₛₚ and feed recovery in hBN-SSWC SHMD. FIG. 13F is a comparison of flux and HUEₛₚ of hBN-SSWC SHMD with the literature data. Each data point represents one published study, except for the data points with varying power densities reported herein.

FIG. 14A-14C, 14D(i)-14D(ii), and 14E show the hBN-coating-enabled long-term operation of SSWC in SHMD. FIG. 14A-14B shows membrane flux, feed recovery (FIG. 14A) and current production (FIG. 14B) within 100 h operation under a power input of 40 kW m⁻². FIG. 14C is Raman intensity mapping at 1,366 cm⁻¹ before (left) and after (right) 100 h operation, revealing a cohesive, uniform coating. Scale bars, 50 μm. The vertical scale bars represent the Raman intensity of the 1,366 cm⁻¹ peak. FIG. 14D(i) is XPS depth profile of hBN-SSWC after operation, and FIG. 14D(ii) is in-depth elemental ratio and B1s and N1s binding energies. FIG. 14E is Tafel curve of hBN-SSWC in 100 gl⁻¹ NaCl solution before and after operation.

FIGS. 15A-15E show magnified hBN-SSWC fabrication and its application in spiral-wound electrothermal SHMD. FIG. 15A shows synthesis of large hBN-SSWC with a length of 85 cm and a width (W) of 2 cm. FIG. 15B is a schematic of a spiral-wound electrothermal SHMD. FIG. 15C is a photograph of the spiral-wound electrothermal SHMD during fabrication. FI, PI, FO, PO represent the inlet (I) and outlet (O) of the feed (F) and permeate (P). d is the diameter of the reactor. FIG. 15D is HUEₛₚ and feed recovery at various feed concentrations and power input intensities. FIG. 15E is comparison of RO, MSF, MED, MVC and this study data in terms of throughput and feed-water salt concentration. Each data point represents one published study, except for the data points with varying power densities reported herein.

### DETAILED DESCRIPTION

The present invention relates to methods of making hexagonal boron nitride coatings upon stainless steel and other ferrous metal/alloy materials, compositions thereof, and methods of using same, such as in electrothermal membrane distillation systems using hexagonal boron nitride coated metal mesh.

In embodiments of the present invention h-BN was for the first time grown stainless steel substrates and ferrous metal/alloy materials, such as on a microporous SSWC. The SSWC has special structure and property: porous, flexible, robust, cheap, and has microscopically uniform high thermal and electrical conductivity, it can provide high intensity of electrothermal energy input. The h-BN nanocoating has excellent thermal conductivity, chemical stability against both strong acids and bases, and high impermeability for any molecules (H₂O etc.), ions (Na⁺, Cl⁻ etc.), and even electron. It provides a perfect chemical and electrical barrier while allowing fast heat transfer. The developed hBN-SSWC is an effective heating material for flowable media.

This h-BN coated materials can be utilized in a variety of application. For instance, the porous hBN-SSWC can be utilized as surface electro-heating element in SHMD operating at household frequency (50 Hz). The SSWC has excellent conductivity (10⁶ S/m), which enables high power input in SHMD to produce ultra-high flux. The excellent insulating property of h-BN coating endows excellent stability of SSWC to work in hypersaline water with a household frequency of only 50 Hz; In addition, the SSWC is cheap and has high strength, and the h-BN coating process is simple and can be magnified easily to large scale application. All these advantages make this invention a highly attractive solution to hypersaline water treatment.

Such membrane can be used in a spiral wound SI-IN/ID configuration. Compared with the plate-and-frame configuration, the spiral wound module has much higher membrane packing density (reached 676 m² m⁻¹) and hence greatly reduces system footprint for a given membrane area.

### Coating of Continuous h-BN Films On Substrates

### Growth of Continuous h-BN

The present invention relates to methods of making hexagonal boron nitride coatings upon stainless steel and other ferrous metal/alloy material substrates. The method utilizes a LPCVD method to grow a continuous h-BN film on the substrate.

The method can include substrate clean, furnace pumping with substrate loading, furnace ramping, film growth, and furnace cooling. It can further include characterizations, such as anti-corrosion and/or high temperature anti-oxidation characterizations.

Large-area, high-quality, uniform, and continuous h-BN thin films were grown directly on stainless steel by a LPCVD method. In the LPCVD method, a precursor and carrier gas can be utilized. Such precursors include borane-ammonia or NH₃ and Diborane. Such carrier gas include pure hydrogen, Ar and He, which carrier gas can be flowed, for example, in the range of 50 sccm to 500 sccm. The pressure can be in the range of 0.01 Torr and 0.5 Torr. During the furnace ramping the furnace temperature can be ramped over a period to a high temperature (such as above 1000° C.), maintained at the high temperature (for growth), and the temperature is then cooled down (such as by naturally cooling down to room temperature).

In embodiments of the present invention, stainless-steel substrates were cleaned with diluted HCl to remove surface oxide. The stainless-steel substrates were pushed to the center of the furnace together. Before performing the LPCVD method, the tube in the furnace was pumped to low pressure (6×10⁻² Torr) and purged with hydrogen gas several times to remove the oxygen gas. Ammonia borane, as the precursor, was placed at the upstream of the furnace, and pure hydrogen (at 200 sccm) was used as the carrier gas. Typically, the furnace was ramped to 1,000° C. in 30-60 min, then ramped to 1,100° C. in 20-60 min and was maintained 5-20 min for films growth. The furnace was then naturally cooled down to room temperature in same hydrogen atmosphere. At this high temperature (1000° C. and above, such as 1000° C.-1100° C.) and in the hydrogen containing reductive atmosphere, the precursors were catalyzed, decomposed, and deposited onto stainless-steel surfaces to form small h-BN crystalline triangles. These triangles subsequently merged together to form large-area and continuous films.

### h-BN Coatings

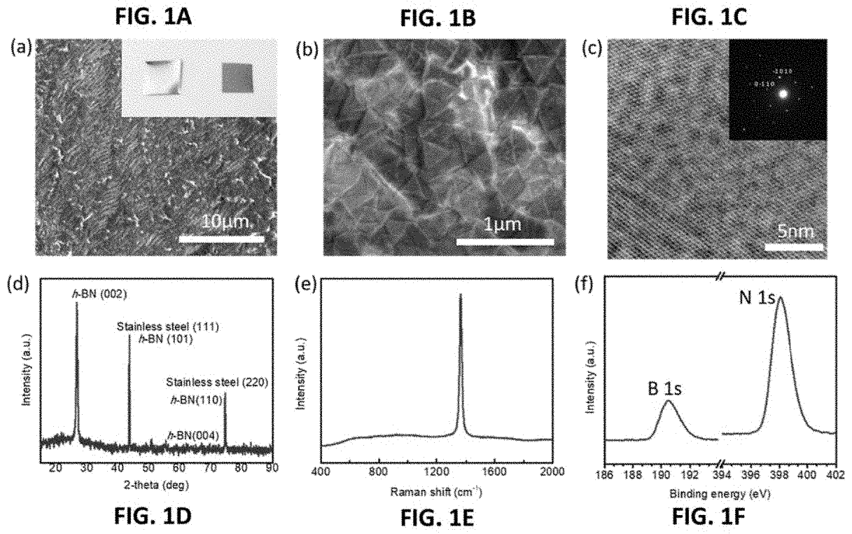

As shown in the inset of FIG. 1A, the shining stainless-steel plate became dark after h-BN growth, and its uniform color was the strong evidence that h-BN thin film was uniformly grown on the stainless-steel substrate. Many regular triangles could be clearly seen in the high-resolution SEM image (FIG. 1B), and its diffraction pattern only exhibited one set of hexagonal symmetrical pattern (FIG. 1C, inset). These agreed well with the P63mc structure of h-BN and demonstrated these triangles were highly crystalline [Kim 2015; Lu 2015]. No obvious pinholes were observed in the continuous h-BN film (FIG. 1C).

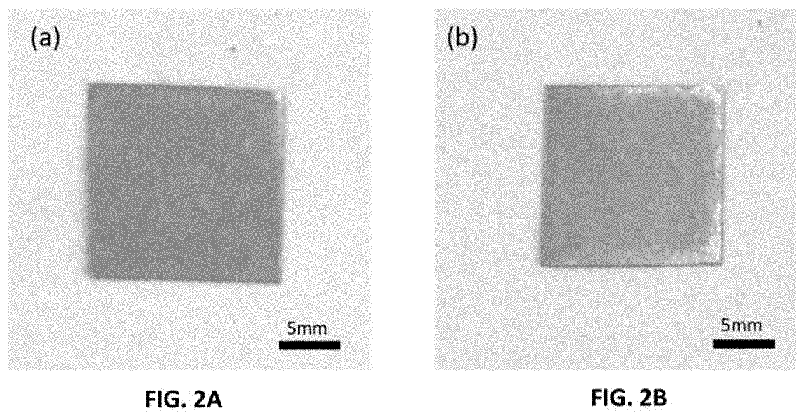

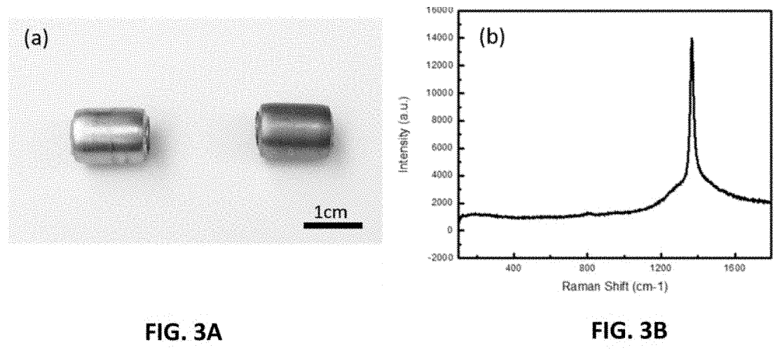

It is worthwhile to note that h-BN can grow on all exposed surfaces of stainless-steel substrates. As shown in FIG. 2, both the top side and the bottom side of the stainless-steel plate had the same and uniform dark color, illustrating h-BN was grown on both sides. Besides the flat surface, h-BN thin films were also successfully grown on curved surfaces, such as stainless-steel tubes (FIGS. 3A-3B). The sharp Raman peak of h-BN on tubes suggested its quality was as good as that grown on the flat substrates.

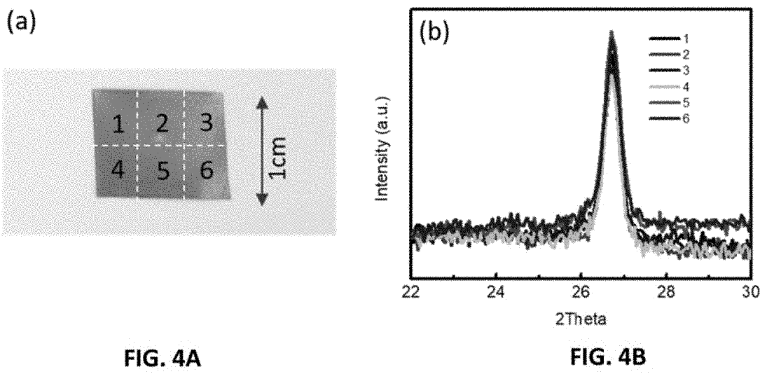

The XRD spectra of h-BN-coated stainless steel revealed a sharp peak at 26.6° (FIG. 1D), which was identified as the (002) peak of h-BN. [Lei 2013]. Similarly, a strong peak at 1,363 cm⁻¹ also appeared in Raman spectra (FIG. 1E). XPS also showed a single sharp peak for B and N elements at 190.5 eV and 398 eV, respectively (FIG. 1F). These were both consistent with reported results and demonstrated the quality of our h-BN thin films grown on stainless steel is as good as that grown on copper or nickel substrate of high purity. [Kim 2015; Lu 2015; Tay 2014]. XRD mapping was also used to characterize the uniformity of h-BN thin films. The XRD (002) peak of every mapping area exhibited the same intensity, providing further evidence of the excellent uniformity of h-BN thin films. (FIGS. 4A-4B).

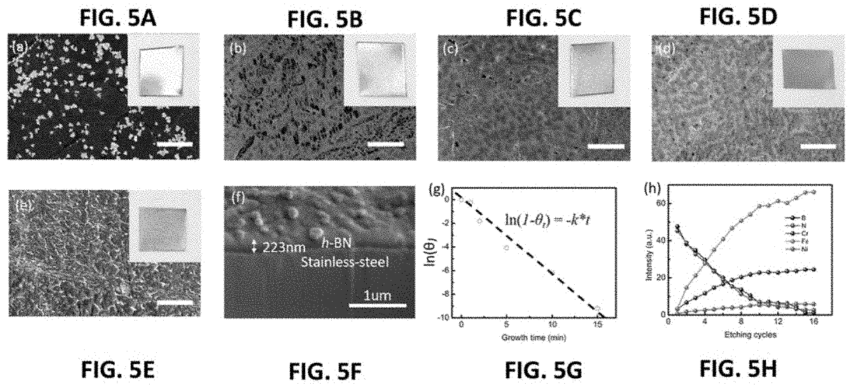

To gain more insights into h-BN thin film growth mechanism, we conducted systematic growth experiment of h-BN on stainless steel with different growth time. FIGS. 5A-5E showed the SEM and optical images of h-BN thin films with a growth period of 1, 2, 5, 10 and 15 min. It could easily be seen when the growth period was extended, more h-BN deposited onto the stainless-steel surface, and the coverage increased significantly. At the same time, the color became darker and darker (FIGS. 5A-5E, insets). The h-BN coverage from these SEM images was extracted and plotted against the growth periods in FIG. 5G. After 1 min growth, the coverage was only about 20%, while it soared to 83% in 2 min and maintained almost 100% after 5 min growth. However, there were still many small pinholes in the h-BN thin films with 5 min growth. It took longer time to fill these pinholes and form continuous and dense films. The coating continuity is an essential requirement for protective coatings. This is because that any pinhole in the protective coating provides an active reaction pathway into the substrate underneath from the surrounding environment. No pinholes were found in continuous h-BN films with 15 min growth (FIG. 5E), suggesting very promising application potential of such coatings. As shown in FIG. 5G, the dashed line is the fitting for the relationship of film coverage versus growth period. It matched with the Lagergren pseudo first-order model, Equation (1) [Ho 1999], indicating that the precursor or intermediate absorption process was the rate-limiting step of h-BN growth. For Equation (1):

ln (θₑ−θₜ)=ln θₑ−k*t (1)

where θₑ and θₜ are the absorption coverage at equilibrium and at any growth time t, k is absorption rate constant, and t is growth periods. θₑ is assumed to be 1 here.

The h-BN thin films inherited the large roughness of the stainless-steel substrate. Therefore, conventional thickness measurement of 2D materials, such as AFM, could not be used here to measure the thickness of h-BN thin films. The cross-section of the h-BN/stainless-steel was prepared by focused ion beam (FIB) and was used to measure the film thickness. As shown in FIG. 5F, the film thickness for 15 min growth time was about 220 nm. The h-BN film thickness is much thicker than films grown on pure copper and nickel substrate [Lu 2015; Liu II 2013; Mahvash 2017]. This is because industrial stainless steel has complicate composition and much smaller dissolution limit for the precursor and its decomposition products. Higher temperature is needed to increase such dissolution and grow h-BN crystals. On the other hand, the surface of industrial stainless-steel substrates after HCl treatment is very rough. It is better to grow a thick film to cover all rough sites. Otherwise, it is easy to form pinholes in h-BN coatings and degrade its protective performances. The XPS depth profile was used to map the element distributions of h-BN/stainless steel along the vertical direction (FIG. 511). After about 15 etching circles, no obvious B and N signal could be detected and the atomic concentration of Fe, Cr, and Ni became 69.7, 19.1, and 6.3%, which was consistent with the pristine stainless-steel element concentration (304 stainless steel, Cr:18%, Ni:6-8%).

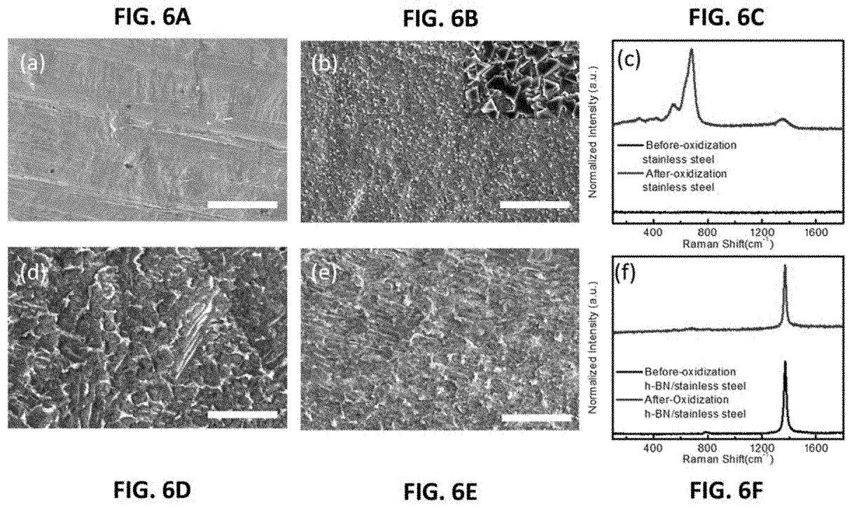

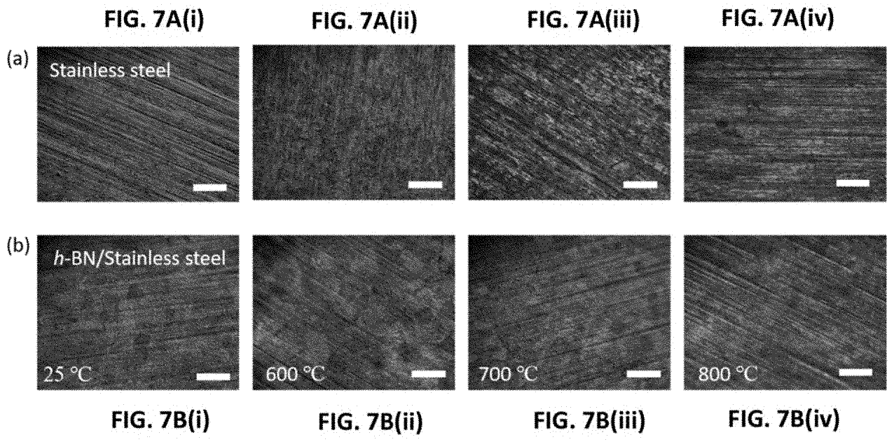

To utilize the excellent stability of h-BN at high temperature, the oxidization-resistant performance of h-BN-coated stainless-steel was characterized [Liu II 2013; Li 2014]. FIGS. 6A-6B and 6D-6E showed SEM images of bare stainless steel and h-BN-coated stainless steel before and after heated in the air for 1 h at 800° C., respectively. It was clear to see that lots of triangular prisms appeared on the bare stainless-steel surface after high-temperature oxidization experiment. (FIG. 6B, inset). The Raman spectra also revealed two broad peaks located at around 546 and 680 cm⁻¹ after oxidization (FIG. 6C), which were identified as the oxidization products (Fe, Cr)₂O₃ [Kuang 2010]. It was also observed that, when the temperature was higher than 600° C., bare stainless steel began to be oxidized and the surface became black gradually. In the white-balanced optical images, many colorful areas appeared, illustrating that its surface morphology was changed (FIGS. 7A(i)-7A(iv) and 7B(i)-7B(iv)). On the other hand, h-BN-coated stainless-steel maintained its original morphology (FIG. 6E), optical color (FIGS. 7B(i-7B(iv)), and Raman spectra (FIG. 6F) even when the temperature was kept at 800° C. The continuous h-BN films effectively separate underneath stainless-steel substrates from high temperature air, leading to intact stainless-steel substrates under high temperature. This is the strong evidence that our h-BN-coating protected stainless steel from oxidization at high temperature.

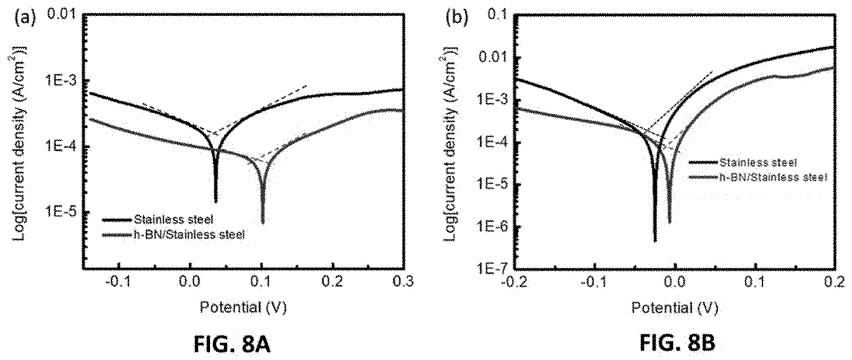

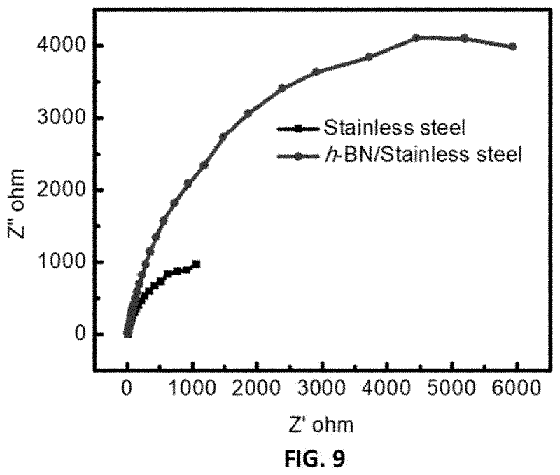

On the other hand, chlorine (Cl) plays an important role in corrosion and most passivation layers for steel-based components could not prevent the diffusion of chlorine effectively. [Chen 2016; Zanotto 2014]. To demonstrate the anti-corrosion performance of the h-BN coating, bare stainless-steel and h-BN-coated stainless-steel plates were immersed into hydrochloride solution (HCl, 1 M) and their Tafel curves were recorded with an electrochemical station. Large-area samples (about 5 mm*10 mm) without any backside seal were directly immersed into the solution in the test to mimic the real working environment and to evaluate anti-corrosion performance of h-BN coating clearly. As shown in FIG. 8A, the Tafel curve of h-BN-coated stainless steel shifted to the bottom right side as compared to bare stainless-steel curve, indicating that it had a lower corrosion current and larger corrosion potential. Specifically, the corrosion current density of h-BN-coated stainless-steel (3.92 E-5 A/cm²) was less than one fourth of that of bare stainless steel (1.92 E-4 A/cm²), and the corrosion potential increased from 0.03 V to 0.11 V. It is noted that the larger the corrosion potential, the less possible the material will corrode. As expected, the electrochemical impedance of h-BN/stainless steel was significantly greater than that of bare stainless steel (FIG. 9), which meant that h-BN coating could effectively resist the diffusion of hydrogen and chloride ions, significantly decrease the corrosion rate and extend the lifetime of the underlying stainless-steel substrate.

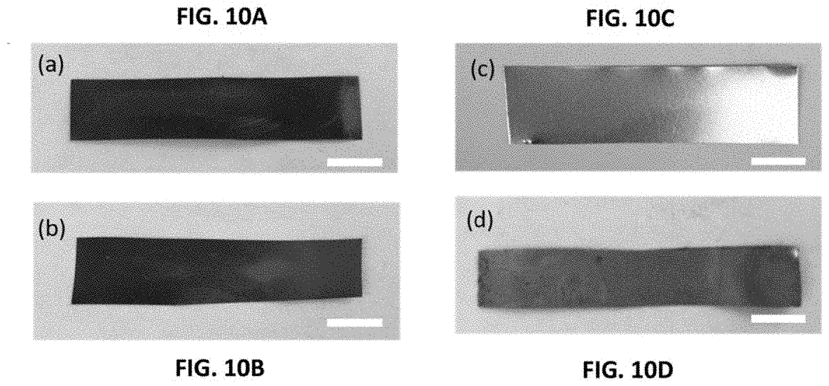

To characterize anti-corrosion performance at elevated temperature and pressure conditions, an autoclave was modified to accommodate three electrodes which were connected with outside electrochemical station along the shallow indented trench on the autoclave. The modified autoclave was placed in a 120° C. oven during the test, and its Tafel curve was recorded. Please note that 0.1 M HCl was used here. Based on the relationship of saturated water pressure and temperature, pressure inside the autoclave was calculated to be about 2.5 bar. As shown in FIG. 8B, similar to the Tafel curves at room temperature, Tafel curve of h-BN-coated stainless steel also shifted to the bottom right side at elevated temperature. The corrosion current density of h-BN coated stainless steel was about 3.6 E-5 A/cm² when the temperature was 120° C. and the pressure was 2.5 bar, which was about 5 times smaller than that of bare stainless steel (1.74 E-4 A/cm²). The corrosion potential also increased from −0.03 V for bare stainless steel to 0 V for h-BN/stainless steel. In addition, the bare stainless-steel plate appeared to be slightly yellow and dark after the high-temperature corrosion test, while h-BN-coated stainless steel remained almost the same dark color and morphology (FIGS. 10A-10D). This is because continuous h-BN films effectively block the direct contact of underneath stainless-steel substrates and corrosive medium. Crystalline h-BN is also very resistant to most chemical corrodents. Therefore, original color and morphology can be maintained after high-temperature corrosion tests. All these results clearly demonstrated that h-BN coating was able to protect stainless-steel substrates from corrosion at both room and elevated temperature conditions. However, some defects, such as grain boundaries in the h-BN film, could provide potential paths for corrosion into the underlying substrates. Especially under high-temperature and high-pressure condition, HCl could easily diffuses into stainless steel underneath through grain boundaries and gradually corrode substrate. Further increasing h-BN grain sizes and reducing overall defects could further improve anti-corrosion performance of h-BN films.

Accordingly, and as shown above the XRD and Raman spectra both exhibited sharp and strong peaks at 26.6° and 1,363 cm⁻¹, respectively, indicting the coating was highly crystalline [Lei 2013]. The bare stainless-steel surface began to be oxidized in the air when the temperature was higher than 600° C., while no obvious changes were observed for h-BN-coated stainless-steel even at the temperature of 800° C. The h-BN coating also showed excellent protection of stainless-steel against corrosion. The corrosion current was less than one fourth of that of the bare stainless steel at both room temperature and elevated temperature conditions.

An effective CVD method has been developed to grow large-area, high quality, uniform, and continuous h-BN thin film directly on industry relevant stainless-steel substrates. The h-BN thin films can grow on all exposed surfaces even with curved and irregular geometries. They are highly crystalline and exhibit strong and sharp Raman and XRD peaks. Extending the growth time improves the h-BN coverage. A uniform, continuous, and dense h-BN film is achieved after 15 min growth. The directly grown h-BN thin films can protect stainless steel from oxidization at high temperature and significantly reduce the corrosion current by about 5 times at both room and elevated temperature conditions. These findings provide for growing thin protective coatings of 2D materials on industry relevant substrates directly and will accelerate the practical applications of h-BN thin films in industry.

Further information regarding the present invention is set forth in Jia 2021 and Jia 2021 Supplementary Information, which are materials co-authored by the inventors.

Uses of Substrates Having Continuous h-BN Films

The h-BN thin films that coat relevant substrates can be utilized in a variety of applications, to take advantage of various characteristics discussed above.

Embodiments of the invention include methods for directly making of a high quality, uniform, and large-area continuous h-BN film on stainless steel plates that is an anti-corrosion coating.

Embodiments of the invention include direct making of high quality, uniform, and large-area continuous h-BN film on substrates of ferrous metal/alloy materials. Such methods can include substrate cleaning, furnace ramping, h-BN film growth that has high temperature anti-oxidation characterizations.

Embodiments of the invention include direct making of high quality, fully covered h-BN film on stainless steel mesh fibres for their applications in membrane distillation unit as a heating layer to treat hypersaline water. Such methods can include substrate cleaning, furnace ramping, hBN film growth, the assemble of hBN coated substrates into a membrane distillation unit and their application in hypersaline water treatment.

An example of such use is for in electrothermal membrane distillation systems using hexagonal boron nitride coated metal mesh for desalination. Other uses include heat conduction, electric insulation, anti-scaling, anti-bacterial and physical protection against corrosion and oxidation under extreme conditions such as high temperature, high electrical voltage and harsh chemicals (strong acid or strong base. etc.).

### Desalination

Desalination is representative of a use of the hexagonal boron nitride coated materials. Desalination is an important technology for drinking water and industrial wastewater treatment. Four billion people around the world face at least one month of water scarcity every year [Dongare 2017], with 1.8 billion people living in countries experiencing absolute water scarcity [Deshmukh 2018]. Desalination plays an important role in the utilization of alternative, saline water resources, in addition to protecting precious freshwater supplies from contamination by industrial wastewaters and brines. Reverse osmosis (RO) is at present the most widely used desalination technology due to its relatively low energy consumption. [Greenlee 2009]. However, the high pressure needed to overcome the osmotic pressure of hypersaline brines precludes its application in the desalination of key industrial waste streams, such as oil and gas produced water and RO concentrates as well as zero-liquid-discharge processes. [Deshmukh 2018; Elimelech 2011]. Conventional thermal desalination methods, such as multi-effect distillation (MED) and multi-stage flash (MSF), are able to desalinate or concentrate brines beyond the salinity limit of RO [Shaffer 2013], but they require extensive infrastructure and high capital costs.

Membrane distillation (MD) is a hybrid thermal-membrane process. In MD, a hydrophobic, porous membrane separates the heated saline feed stream and the cool permeate stream. The temperature difference between the feed and permeate streams creates a gradient in the partial vapour pressure of the water vapour, driving its trans-port across the membrane. [Lawson 1997]. After diffusing through the membrane, the water vapour condenses on the permeate side, producing pure water. The technology has the high salinity capability of conventional thermal desalination, enjoys the compact modular configuration of membrane systems, features low operating pressure and relatively low temperature, and it is also expected to be less prone to fouling than RO. [Tow 2018]. However, it suffers from several inherent limitations that result in very low thermal efficiencies. Specifically, temperature polarization on both sides of the membrane reduces the vapour pressure difference and hence the flux; the average transmembrane temperature difference decreases with increasing feed channel length, resulting in decreasing average flux with increasing membrane module size; and limited heat capacity of the feed water relative to the high enthalpy of evaporation results in very low single-pass water recovery. In addition, heating the feed externally increases the system complexity and potential thermal energy loss.

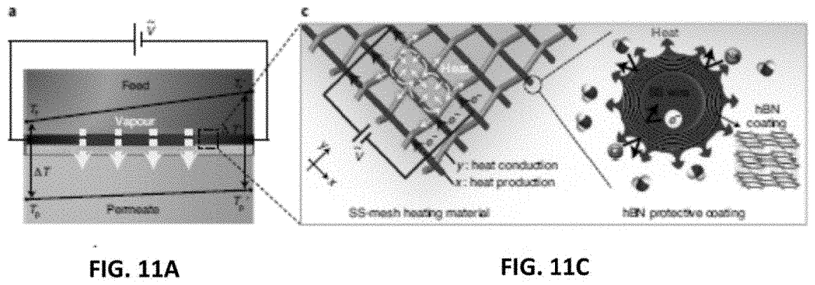

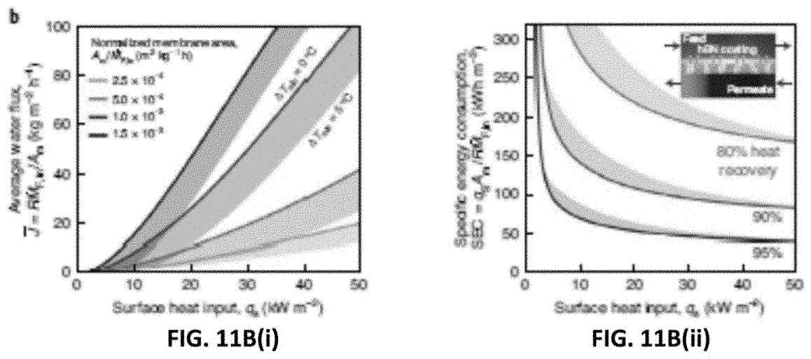

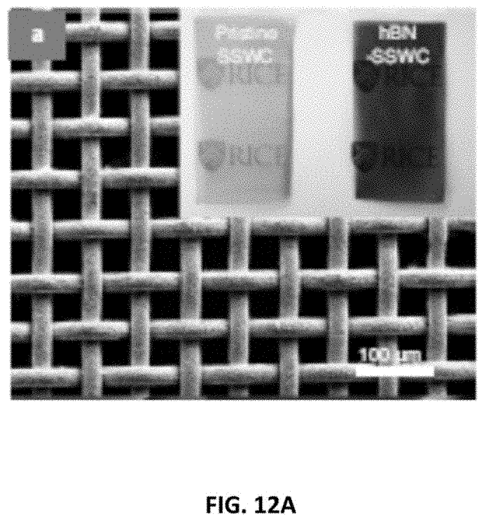

Directly heating the feed stream at the membrane-solution interface can be utilized to address these limitations. See FIG. 11A. Both solarthermal [Dongare 2017] and electrothermal [Dudchenko 2017] coatings have been developed to achieve surface heating membrane distillation (SHMD). Solarthermal membranes utilize sunlight as the energy source, although water production rates are limited by its low energy intensity. Electrothermal MD utilizes spacer induction heating [Tan 2020] or Joule heating through an electrically conducting coating [Dudchenko 2017], allowing the simple control of the energy input, although spacer heating heats the bulk feed water and is not considered to be SHMD. Dudchenko 2017 successfully demonstrated desalination using an MD membrane with an electrothermal coating consisting of multi-walled carbon nanotubes and polyvinyl alcohol (MWCNT/PVA). The MWCNT/PVA coating, however, was susceptible to electrochemical corrosion in saline water, requiring high-frequency (10 kHz) a.c. power to protect it from degradation. Furthermore, its relatively low electrical conductivity together with its low electrochemical stability limit the surface energy input and hence the transmembrane water flux. [Boo 2017] 10. To be part of practical desalination technology, the electrothermal coating must possess the following: (1) high corrosion resistance, (2) high electrical conductivity, (3) high thermal conductivity, (4) superb electric insulation from the sur-rounding saline water and (5) high porosity. Finite-difference modelling by the Applicant illustrates the extraordinary increase in the average water flux (FIG. 11B(i)) and decrease in the specific energy consumption (SEC) (FIG. 11B(ii)) with surface heat input, underscoring the importance of heating materials that can support high-energy operation.

Stainless-steel wire cloth (SSWC) is porous, flexible, robust and cheap, and it has microscopically uniform high thermal (12-45 W m⁻¹ K⁻¹) and electrical (bulk conductivity of 1.5×106 S m⁻¹) conductivity. Although SSWC possesses outstanding anticorrosive performance in wet air and saline water, it faces the same challenge as the MWCNT/PVA coating when used in an electrothermal unit: electrochemical corrosion. One potential solution is to apply an insulating coating on the surface of the SSWC to prevent contact with saltwater and eliminate electrochemical corrosion. FIG. 11C. An effective coating would allow an SHMD system to be powered by low-frequency a.c. or even d.c. power sources.

Hexagonal boron nitride (h-BN) is a van der Waals layered material, with a very similar lattice structure to graphene at the mono-layer limit. It possesses many desirable properties including tunable thickness [Song 2010], ultraflat saturated surface [Dean 2010], mechanical robustness [Falin 2013], large insulating bandgap and high dielectric constant [Watanabe 2004], excellent thermal conductivity [Jiang 2018], chemical stability against both strong acids and bases [Chilkoor 2018; Zhang J 2016], and high impermeability [Hu 2014]. Consequently, h-BN has been demonstrated to be a promising passivating coating for chemically active substrates in harsh environments. [Liu II 2013]. Compared with other protective coating materials such as graphene, polymers and atomic-layer-deposited coatings [Costescu 2004; Abdulagatov 2011], the electrically insulating yet highly thermally conducting properties of h-BN combined with its impermeability to electrons, salt ions and gas and water molecules (FIG. 11C) are especially attractive as it provides a perfect chemical and electrical barrier while allowing rapid heat transfer. For the electrothermal heating of water, this eliminates Faradaic reactions such as water splitting on the heating element surface that may damage the membrane material, while maintaining efficient heat exchange.

As noted above, although high-quality h-BN nanofilm growth has been realized on nickel [Liu 12013], copper [Pakdel 2012], iron [Sun 2018], and their alloy substrates [Lu 2015; Lu 2017], growing high-quality h-BN nanofilms on more commonly used metal substrates such as stainless steels has not been achieved, let alone the direct growth of h-BN on porous SSWC considering its complex geometry.

Accordingly, the use of the present invention has applicability is such by growing high-quality h-BN nanocoatings on SSWC surfaces (hBN-SSWC) and applying them in electro-thermal SHMD for the desalination of hypersaline waters.

When laminated on a commercial PVDF (polyvinylidene difluoride) membrane, uniform Joule heating in the SSWC generated by a voltage at household frequency (50 Hz) transfers efficiently to the saline feed water through the hBN coating (FIG. 11C), leading to the rapid evaporation of water on the membrane surface and producing very high vapour fluxes. The exceptional electrical insulation and physical protection provided by the h-BN nanocoating prevents chemical and electrochemical corrosion and any other undesirable reactions, ensuring long-term, stable performance of the SHMD in the desalination of hypersaline waters.

### Growth of High-Quality h-BN on SSWC

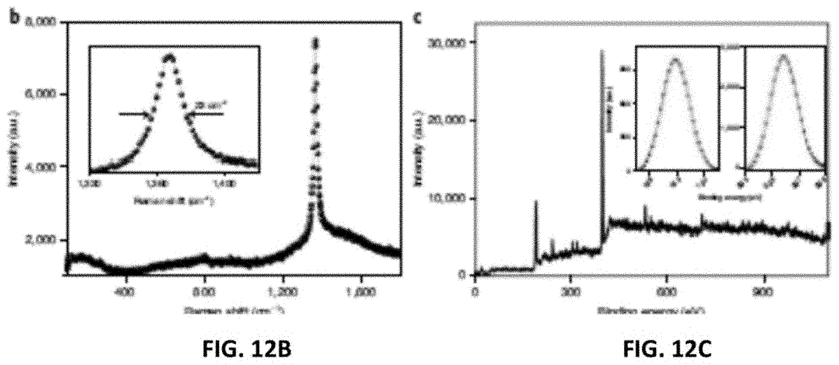

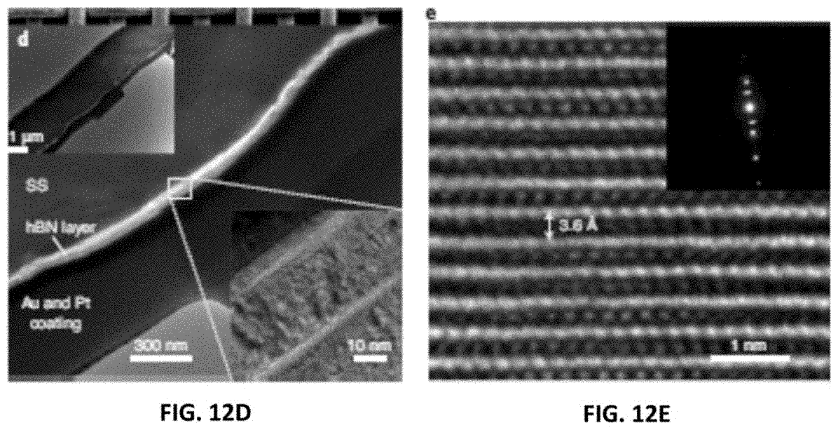

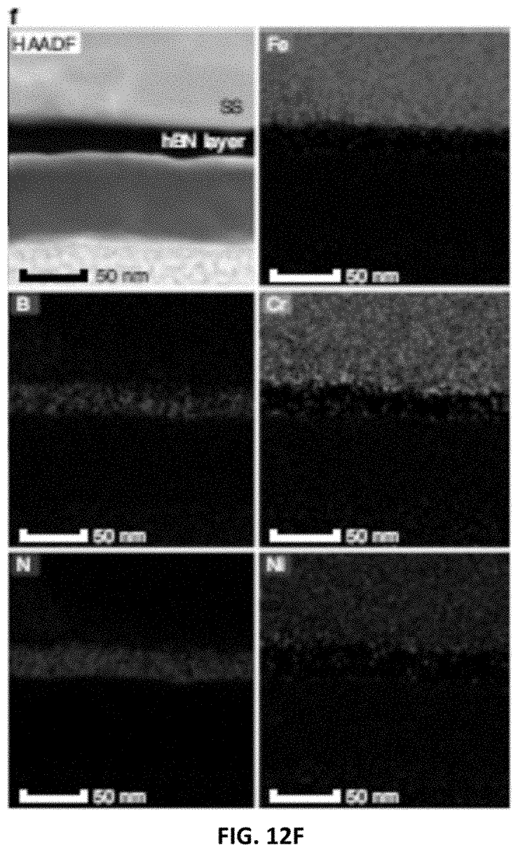

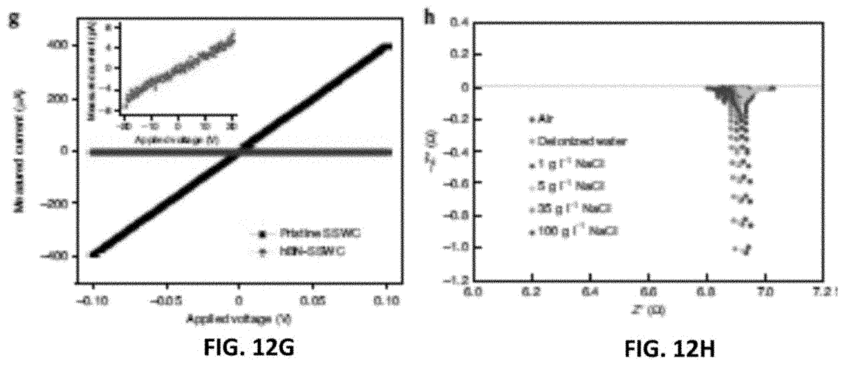

The Fe and Ni elements in SSWC (ASTM 316) are involved for direct h-BN growth (Appendix, Supplementary Section 4). The h-BN nanocoating was directly grown using a conventional low-pressure chemical vapour deposition method on a 400-mesh-number SSWC. (FIG. 12A). After h-BN growth, the SSWC turned dark brown and maintained its porous structure and excel-lent flexibility. The Raman spectrum (FIG. 12B) shows a strong, narrow peak located at 1,366 cm⁻¹ with full-width at half-maximum (FWHM) of 23 cm⁻¹, indicating the very high crystallinity of h-BN.

The X-ray photoemission spectroscopy (XPS) spectrum (FIG. 12C) revealed prominent N1s and B1s peaks, both well fitted using single Gaussian distribution with the peak centres located at 396.4 and 188.9 eV, respectively. These peaks as well as the stoichiometric atomic ratio (B:N=50:50) showed that the h-BN coating was of high quality without any elemental doping (for example, carbon atoms from the stainless-steel (SS) matrix). Cross-sectional transmission electron microscopy (TEM) images (FIG. 12D) confirmed the layered structure of the as-grown h-BN with a thickness of 80-100 nm over the observed area. Sufficient coating thickness is necessary to avoid ‘weak points’ caused by potential defects in each h-BN layer, particularly in large areas. The selected area diffraction pattern with extended, bright diffraction dots confirms the well-aligned layered structure. Atomic-resolution TEM (FIG. 12E) reveals a layered structure of h-BN with interlayer spacing of ˜3.6 Å and lattice constant of ˜2.3 Å. As the h-BN is directly grown on a curved surface of SS fibres, the cross-sectional TEM represents bent h-BN layers. Energy-dispersive spectroscopy mapping (FIG. 12F) shows the uniform distribution of B and N elements throughout the h-BN layer and a clear interface between the h-BN layer and SS matrix. It is noteworthy that N and B are also observed on the top surface of the SS matrix, indicating a possible diffusion-nucleation growth mechanism. [Zhang Z 2016].

The direct growth of high-quality h-BN layers on SSWC enables outstanding insulation and anticorrosion performance in a unique environment in electrothermal SHMD. The electrical conductivity across the h-BN nanocoating was characterized using an applied d.c. voltage (FIG. 12G). It shows resistance greater than 3×1012Ω over an applied d.c. voltage between −20 and 20 V (inset of FIG. 12G), allowing high-power-input applications of hBN-coated SSWC. The ultra-high electrical resistance, chemical inertness and impermeability of the h-BN coating provide a complete barrier to mass (for example, salt ions and water molecules) and charge exchange between the saline water and SSWC, preventing any potential chemical and electrochemical reactions (FIG. 11C). This is demonstrated by the electrochemical impedance spectroscopy data, showing that the impedance of hBN-SSWC remained unchanged under the solution conditions over a wide range of salt concentrations (FIG. 12H) and pH values, while the pristine SSWC shows a dramatic impedance change when tested in high-salinity water. In addition, the h-BN nanocoating efficiently conducts heat from the SSWC to the surrounding environment: the coated SSWC could support intensive power input (as high as 100 kW m⁻²) and produce temperatures higher than 200° C.

### SHMD Enabled by hBN-SSWC Joule Heating

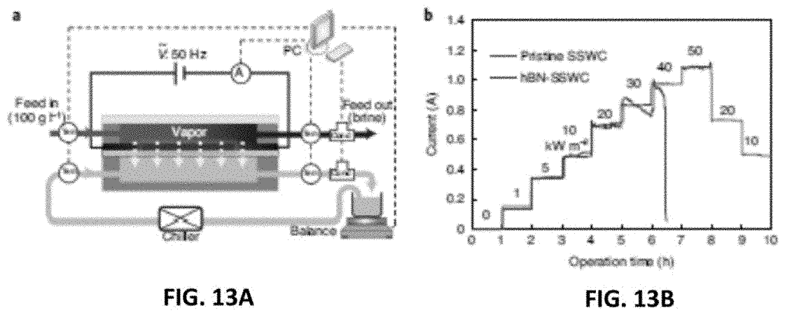

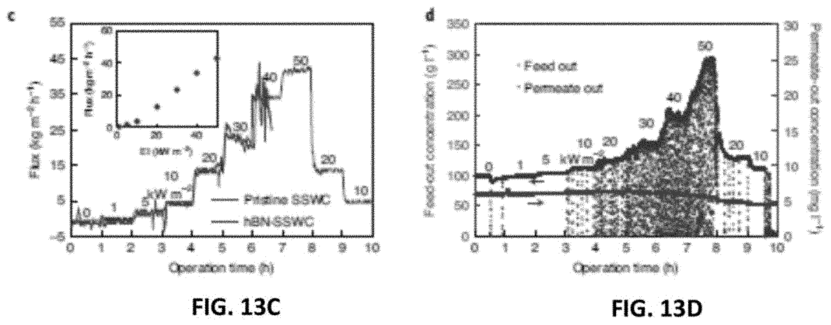

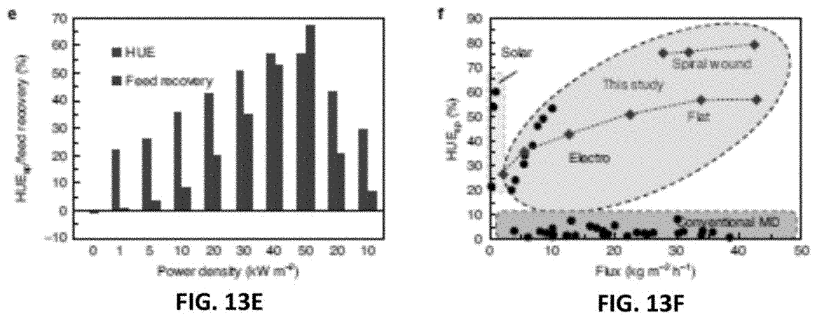

The high-quality h-BN nanocoating (FIG. 12A-12F) and its protective barrier function (FIGS. 12G-12H) show that hBN-SSWC could be used for high-efficiency electrothermal SHMD. By attaching the pristine or hBN-coated SSWC on top of a PVDF membrane in the feed chamber of a custom-built SHMD cell, hypersaline water (100 g 1-l NaCl) was desalinated under the single-pass operation mode at various input power densities (1-50 kW m⁻²). (FIG. 13A). Current production (FIG. 13B), membrane flux (FIG. 13C), effluent salt concentration (FIG. 13D) and temperature of the influent and effluent of the feed and permeate were monitored. While consistently maintaining salt rejection of >99.9%, the membrane flux increased nonlinearly from 0.32±0.03 to 42.7±0.8 kg m⁻² h⁻¹ when the input power density increased from 1 to 50 kW m⁻². The flux of 42.7±0.8 kg m⁻² h⁻¹ in the hBN-SSWC SHMD is five times as high as that generated by the MWCNT/PVA coating (˜8.5 kg m⁻² h⁻¹ [Dudchenko 2017], and almost an order of magnitude higher than that generated by photothermal SHMD membranes (0.5 kg m⁻² h⁻¹ [Dongare 2017]).

As the base membranes used in these studies have similar permeability, the large difference in membrane flux can be attributed to the difference in the energy input intensity achieved, which are 50.0, 11.1 and ˜1.0 kW m⁻² for the hBN-SSWC, MWCNT/PVA and photothermal SHMD membranes, respectively. In conventional MD, the flux can be >30 kg m⁻² h⁻¹ with a cross-membrane temperature difference (ΔT) of 30-50° C. However, ΔT decreases with the membrane length; achieving a high temperature difference in large membrane modules is a major challenge in process scale up. [Chen 2009]. In the present invention, heat is produced on the membrane surface. The temperature of the feed stream, ΔT, and hence the local membrane flux increase with the mem-brane module length (FIGS. 11A and 11B(i)-11B(ii)). The average membrane flux of the module, therefore, increases with the increasing module length l.

At 50 kW m⁻², the high membrane flux resulted in highly concentrated brine (302.9 g l⁻¹), corresponding to 67.0% single-pass water recovery. It is important to note that single-pass water recovery in conventional MD is limited to 6.4% [Lin 2014] due to the decreasing feed temperature explained above. In the hBN-SSWC SHMD system, both membrane flux and single-pass water recovery can be further increased by increasing the membrane module length or reducing the feed-flow rate (that is, increasing the hydraulic retention time in the module). This is contrary to the case with conventional MD, which requires higher feed-flow rates to minimize the temperature polarization and supply the thermal energy for evaporation.

One important performance metric in MD is energy efficiency, which usually depends on the heat utilization efficiency (“HUE”) of the MD reactor itself, and the recovery and reuse of heat from the brine and the latent heat in the permeate vapour, the latter usually achieved by recirculating the brine and recovering the latent heat using an external heat exchanger. [Lin 2014]. Conventional MD suffers from very low single-pass HUE (HUEₛₚ) (0.76-8.09% [Naidu 2017; Luo 2017; Efome 2016; Merocq 2010]) due to its inherent limitations. Carefully designed heat recovery strategies can greatly improve the overall HUEₛₚ to above 50-80% [Tan 2010; Zhang 2015; Leitch 2016; Deshmukh 2017]. The same strategies can also be used in SHMD systems to improve the energy efficiency.

Previously reported SHMD studies, either photothermal or electrothermal, achieved much higher HUEsp, but the flux was limited (FIG. 13F) under low-input-energy intensity. As shown in FIGS. 11B(i)-11B(ii) and 13C, the membrane flux increases nonlinearly with the energy intensity because the water vapour pressure increases exponentially with the temperature as described by the Antoine equation. [Alsaadi 2013; Al-Obaidani 2008]. Higher flux directs more energy towards evaporation versus heating the feed stream, resulting in an increase in HUEsp with the energy input.

The high electrical conductivity and excellent protective properties of hBN-SSWC enabled high-energy input (50 kW m⁻²), thereby realizing HUEₛₚ and flux values (56.8% and 42.7 kg m⁻² h⁻¹, respectively; FIG. 13E-13F) that are much higher than those for either conventional MD or previously reported SHMD. It should be noted that the measured HUEₛₚ is a function of the mem-brane size and would be higher with better thermal insulation of the experimental system.

It is worth noting that the h-BN nanocoating is critical for achieving the observed high performance. As a comparison, the pristine SSWC experienced severe disruption in performance when the input power density increased to 30 kW m⁻², as reflected by the current (FIG. 13B), flux (FIG. 13C) and feed-effluent temperature data. It stopped working at 40 kW m⁻² due to corrosion-damage-induced breakdown. The scanning electron microscopy (SEM) images taken after the MD experiments confirmed that severe corrosion occurred on the pristine SSWC, while hBN-SSWC remained intact due to protection provided by the h-BN nanocoating. A careful examination of the underlying PVDF membrane showed no damage on its porous structure after operation at 50 kW m⁻². The liquid entry pressure also remained unchanged before (0.325±0.015 MPa (±s.d) for PVDF) and after (0.323±0.007 MPa (±s.d) for the hBN-SSWC-coated PVDF) operation. These results suggest that the high heating intensity of hBN-SSWC did not cause any deterioration of the PVDF membrane.

### Stability of hBN-SSWC in SHMD Operation

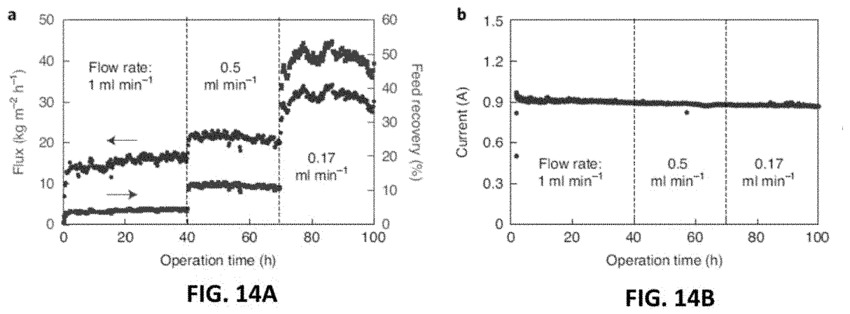

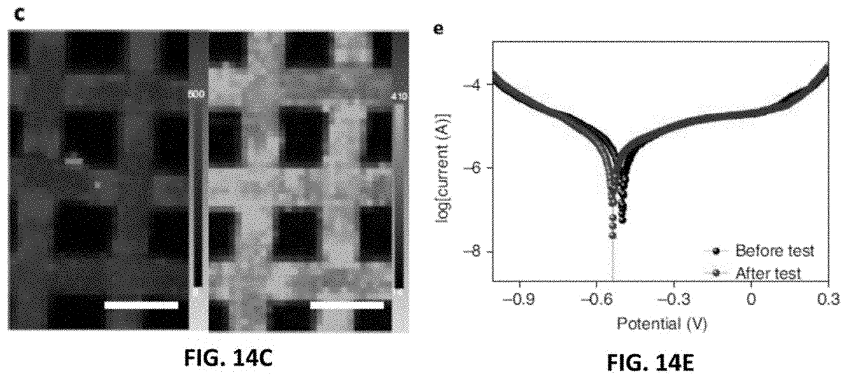

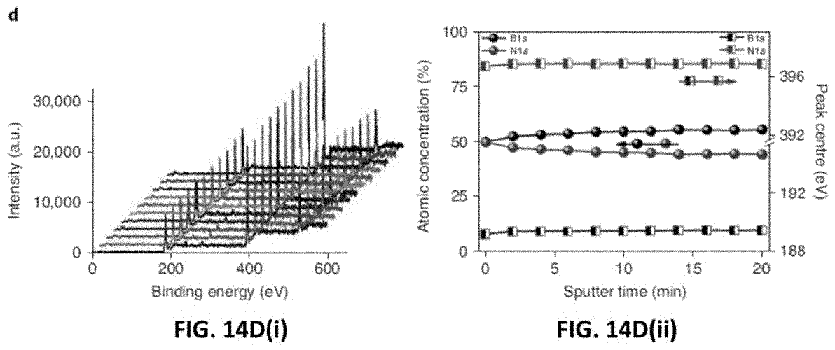

The long-term stability of hBN-SSWC was evaluated by operating the SHMD system at a constant power input density of 40 kW m⁻²and varying feed-flow rates (1, 0.5 and 0.17 ml min') for 100 h. The performance was very stable under all the operating conditions in terms of flux (FIG. 14A), feed recovery and permeate quality (salt concentration ˜5 mg l⁻¹). The current production also stabilized at 0.89±0.03 A at all the feed-flow rates, indicating negligible impact of the feed-flow rate or brine concentration (FIG. 14B). Raman mapping (FIG. 14C) and XPS characterization (FIGS. 14D(i)-14D(ii)) of hBN-SSWC after the 100 h experiment showed no detectable change in the h-BN nanocoating.

Further, h-BN has been reported to withstand extreme conditions with temperature up to 800° C. [Tran 2016], voltage up to 1.2×107 V cm⁻¹ [Hattori 2015] and a broad range of pH (2-14). In the electrothermal SHMD operation, although a high power density (40 kW m⁻²) was utilized, the temperature on the hBN-SSWC surface is <100° C. due to the presence of liquid water. The voltage gradient across the h-BN nanocoating (˜106 V cm⁻¹) was also much lower than its breakdown threshold. Because h-BN is non-abrasive and has similar thermal expansivity to SS, it is also unlikely to crack when the temperature varies. The Tafel test further supports that hBN-SSWC showed negligible change before and after the SHMD experiment (FIG. 14E), indicating no degradation or damage of the h-BN nanocoating.

### Magnified hBN-SSWC in Spiral-Wound Electrothermal SHMD

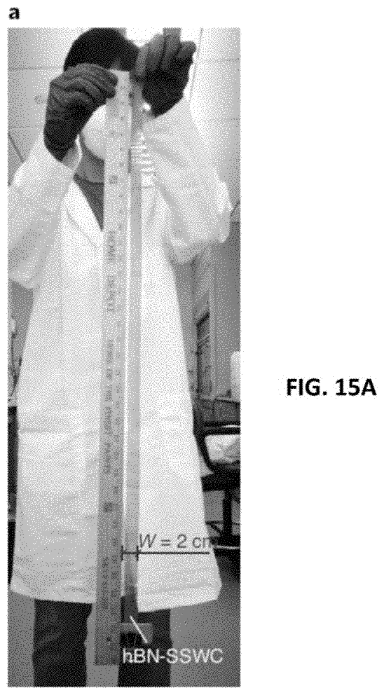

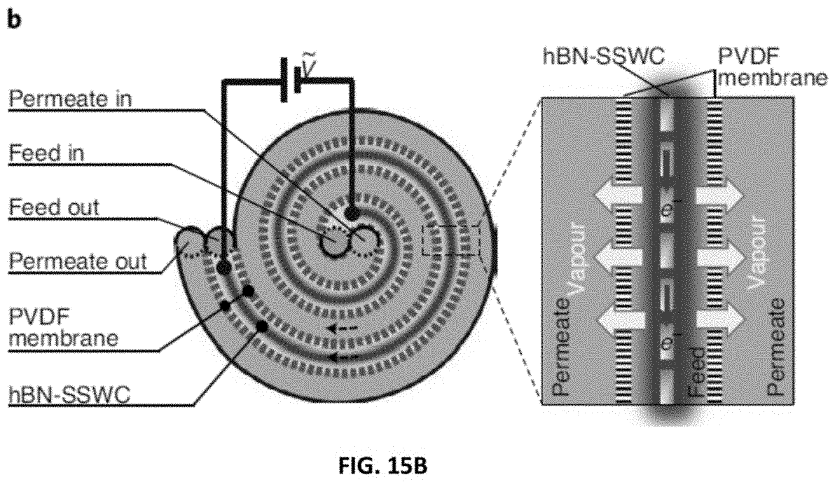

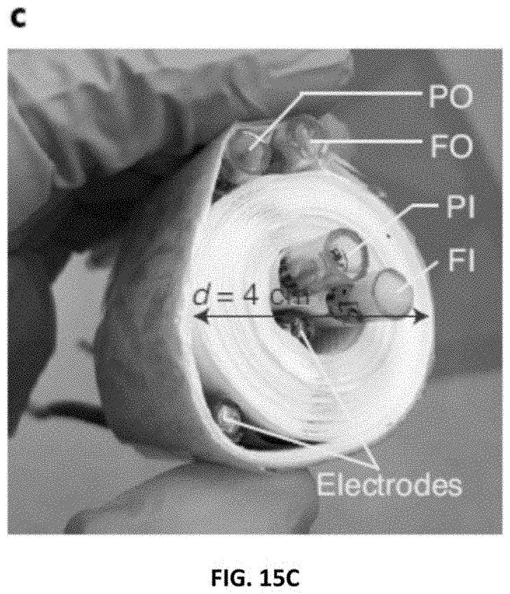

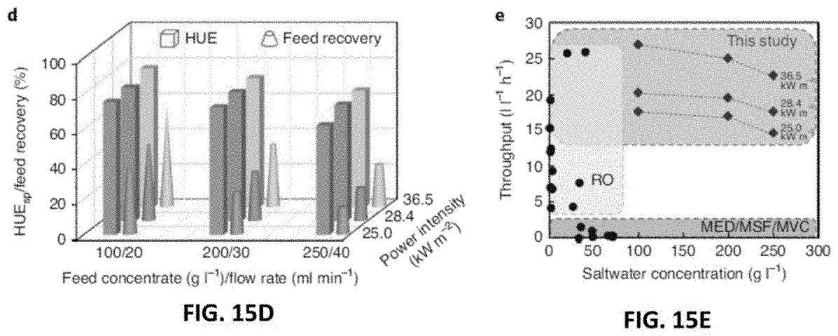

The flexibility and porous structure of SSWC facilitates the large-scale growth of the h-BN coating in a common tube furnace. In our study, an hBN-SSWC sample of 2 cm×85 cm was prepared in a furnace with a tubing diameter of 4.6 cm (FIG. 15A). Raman study showed that a high-quality, ˜50 nm h-BN coating was uniformly grown over the whole surface of the large SSWC sample. With the large hBN-SSWC sample, a spiral-wound SHMD module was constructed with the hBN-SSWC sandwiched between two flat-sheet PVDF membranes and rolled into a cylindrical housing. The feed stream flows in the channel formed between the two membrane sheets, while the cold permeate stream flows outside the ‘sack’ (FIGS. 15B-15C).

Compared with the plate-and-frame configuration (FIG. 13A), the spiral-wound module has much higher membrane packing density (676 m² m⁻³) and hence greatly reduces the system footprint for a given membrane area. More importantly, this design allows the hBN-SSWC coating to heat two membrane sheets at the same time and minimizes heat dissipation to the environment, greatly increasing the water production rate and reactor HUEₛₚ. With 36.5 kW m⁻² power input, the volumetric energy intensity reached 23.2 kW l⁻¹, producing flux of 42.4 kg m⁻²h⁻¹ (based on the hBN-SSWC area) when desalinating 100 g l⁻¹ NaCl, which is 30.7% higher than that obtained using the plate-and-frame configuration at 40 kW m⁻² (33.8 kg m⁻² h⁻¹). Similarly, the reactor HUEₛₚ increased from 56.8% (FIG. 13F) to 79.1% (FIG. 15D).

The high packing density and reactor HUEₛₚ of the spiral-wound module result in a very high throughput (volume of clean water produced per unit reactor volume per unit time) of 27.011⁻¹ h⁻¹ when desalinating a 100 g l⁻¹ NaCl solution using a power input of 36.5 kW m⁻² (FIG. 15E). Together with its capability to treat feed streams of very high salt concentration (FIG. 15E), it provides a compact, high-throughput solution for hyper-saline water treatment, filling a critical technological gap in current thermal and RO-based desalination technologies. As shown in FIG. 15E, RO systems are highly compact with volumetric flux up to 2611⁻¹ h⁻¹, but they are limited to ˜80 g l⁻¹ in feed-water salt concentration. Thermal desalination methods such as MSF, MED and mechanical vapour compression (MVC) can handle a wide range of salt concentrations, but they have very low through-put (usually <1 ll⁻¹ h⁻¹) and hence the reactor size is very large.

Clearly, a desalination technology that can offer high membrane flux over a wide range of salt concentrations and low energy consumption is highly desirable. Intensive consumption of electricity—a higher-quality form of energy compared with heat—is the main concern in electricity-powered MD. In the spiral-wound SHMD, the higher HUEₛₚ (79.1%) realized an energy consumption of 875.8 kWh m⁻³ of clean water produced with no heat recovery. Despite being one of the lowest energy consumptions achieved in any MD processes without heat recovery, it is much higher than those of RO and other thermal technologies. Efficient heat recovery is critical to lower energy consumption for any MD systems. Incorporating effective heat recovery measures, such as brine recirculation and vapour heat exchange with raw feed water through multi-stage or multi-effect designs, have the potential to reduce the SEC to under 50 kWh m⁻³ (FIGS. 11B(i)-11B(ii)).

The heat input and membrane area per unit feed-flow rate of the hBN-SSWC SHMD system can be tailored to maximize the average water flux, reduce the areal foot-print or minimize the SEC depending on the specific application. The spiral-wound hBN-SSWC SHMD would be a highly attractive solution to treat hypersaline waste streams, such as RO brine, oil and gas produced water and food-processing wastewater, as well as zero liquid discharge at high throughput, particularly where the system footprint is critical (such as offshore platforms). Other attractive features of the system include simplicity (for example, no need for external heater or feed recirculation loop), scalability (modular configuration with no restriction on module length) and the capability of operating using a household power source (50 Hz). When available, alternative energy sources including low-grade industrial waste heat, solarthermal energy and geothermal heating can be used to reduce the electrical energy consumption of hBN-SSWC SHMD, while electrothermal heating using hBN-SSWC ensures the high throughput and water recovery needed.

### Utilization

Pre the present invention, high-quality h-BN nanocoating was successfully grown on SSWC, allowing it to function as an efficient and stable Joule heater in SHMD. The h-BN coating serves as an excellent barrier to mass and charge exchange between hypersaline water and SSWC, while allowing efficient heat transfer. When combined with a commercial PVDF membrane in SHMD, hBN-SSWC enabled the high-performance desalination of hypersaline water with a power source of house-hold frequency (50 Hz), simultaneously producing very high module-scale water flux, single-pass water recovery, reactor heat utilization efficiency and near-saturated brine. The hBN-SSWC also demonstrated excellent stability during long-term operation, with no observable (electro)chemical degradation or scraping of hBN-SSWC. The high flexibility and porosity of the SSWC enabled the large-scale uniform growth of the hBN coating using existing chemical vapour deposition methods. The development of a novel yet simple spiral-wound SHMD module further improved the single-pass heat utilization efficiency and achieved very high reactor throughput, rendering it to be a highly attractive solution for hyper-saline water treatment. The synergistic combination of material and system design in this study demonstrates how the unique properties of nanomaterials—when strategically integrated into a process—addresses highly challenging engineering problems and overcomes limitations of conventional technologies.

### Additional Utility

The thin and porous structure, high resistance to corrosion and capability of generating high heat intensity of hBN-SSWCs may find broader applications in water and wastewater treatment as well as other industrial processes where the reaction kinetics limits the treatment efficiency. For example, it can be used as the support for catalysts in thermal-catalytic filters to enhance the catalytic reaction kinetics; it can also be used to deliver uniform, high heat intensity for the pyrolysis of refractory substances.

Moreover, the h-BN coated substrates can be utilized for heat conductor, electric insulation, anti-scaling, anti-bacterial and physical protection against corrosion and oxidation under extreme conditions such as high temperature, high electrical voltage, and harsh chemicals (strong acid or strong base) etc.

Further information regarding the present invention is set forth in Zuo 2020 and Zuo 2020 Supplementary Information, which are materials co-authored by the inventors.

While embodiments of the invention have been shown and described, modifications thereof can be made by one skilled in the art without departing from the spirit and teachings of the invention. The embodiments described and the examples provided herein are exemplary only, and are not intended to be limiting. Many variations and modifications of the invention disclosed herein are possible and are within the scope of the invention. The scope of protection is not limited by the description set out above, but is only limited by the claims which follow, that scope including all equivalents of the subject matter of the claims.

The disclosures of all patents, patent applications, and publications cited herein are hereby incorporated herein by reference in their entirety, to the extent that they provide exemplary, procedural, or other details supplementary to those set forth herein.

Amounts and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of approximately 1 to approximately 4.5 should be interpreted to include not only the explicitly recited limits of 1 to approximately 4.5, but also to include individual numerals such as 2, 3, 4, and sub-ranges such as 1 to 3, 2 to 4, etc. The same principle applies to ranges reciting only one numerical value, such as “less than approximately 4.5,” which should be interpreted to include all of the above-recited values and ranges. Further, such an interpretation should apply regardless of the breadth of the range or the characteristic being described.

Unless defined otherwise, all technical and scientific terms used herein have the same meaning as commonly understood to one of ordinary skill in the art to which the presently disclosed subject matter belongs. Although any methods, devices, and materials similar or equivalent to those described herein can be used in the practice or testing of the presently disclosed subject matter, representative methods, devices, and materials are now described.

Following long-standing patent law convention, the terms “a” and “an” mean “one or more” when used in this application, including the claims.

Unless otherwise indicated, all numbers expressing quantities of ingredients, reaction conditions, and so forth used in the specification and claims are to be understood as being modified in all instances by the term “about.” Accordingly, unless indicated to the contrary, the numerical parameters set forth in this specification and attached claims are approximations that can vary depending upon the desired properties sought to be obtained by the presently disclosed subject matter.

As used herein, the term “about” and “substantially” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

As used herein, the term “substantially perpendicular” and “substantially parallel” is meant to encompass variations of in some embodiments within ±10° of the perpendicular and parallel directions, respectively, in some embodiments within ±5° of the perpendicular and parallel directions, respectively, in some embodiments within ±1° of the perpendicular and parallel directions, respectively, and in some embodiments within ±0.5° of the perpendicular and parallel directions, respectively.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C, and D.

### REFERENCES

Abdulagatov, A., et a “Al₂O₃ and TiO₂ atomic layer deposition on copper for water corrosion resistance,” ACS Appl. Mater. Interfaces, 2011, 3, 4593-4601 (“Abdulagatov 2011”).

Al-Obaidani. S., et al., “Potential of membrane distillation in seawater desalination: thermal efficiency, sensitivity study and cost estimation,” J. Membr. Sci., 2008, 323, 85-98 (“Abdulagatov 2008”).

Alsaadi, A. S., et al., “Modeling of air-gap membrane distillation process: a theoretical and experimental study,” J. Membr. Sci., 2013, 445, 53-65 (“Alsaach 2013”).

Avsar, A., et al., “Air-stable transport in graphene-contacted, fully encapsulated ultrathin black phosphorus-based field-effect transistors,” ACS Nano, 2015, 9, 4138-4145 (“Avsar 2015”).

Boo, C., et al, “Thermal desalination membranes: carbon nanotubes keep up the heat,” Nat. Nanotechnol., 2017, 12, 500-503 (“Boo 2017”).

Britnell, L., et al., “Electron tunneling through ultrathin boron nitride crystalline barriers,” Nano Lett., 2012, 12, 1707-1710 (“Britnell 2012”).

Chandni, U., et al., “Evidence for defect-mediated tunneling in hexagonal boron nitride-based junctions,” Nano Lett., 2015, 15, 7329-7333 (“Chandni 2015”).

Chen, T.-C., et al., “Theoretical modeling and experimental analysis of direct contact membrane distillation,” J. Membr, Sci., 2009, 330, 279-287 (“Chen 2009”).

Chilkoor, G et al., “Hexagonal boron nitride: the thinnest insulating barrier to microbial corrosion” ACS Nano, 2018, 12, 2242-2252 (“Chilkoor 2018”).

Costescu, R., et at., “Ultra-low thermal conductivity in W/Al₂O₃ nanolaminates,” Science, 2004, 303, 989-990 (“Costescu 2004”).

Dean, C. R., et al., “Boron nitride substrates for high-quality graphene electronics,” Nat. Nanotechnol., 2010, 5, 722-725 (“Dean 2010”).

Deshmukh, A., et al., “Membrane distillation at the water-energy nexus: limits, opportunities, and challenges,” Energy Environ. Sci., 2018, 11, 1177-1196 (“Deshmukh 2018”).

Deshmukh A., et at, “Understanding the impact of membrane properties and transport phenomena on the energetic performance of membrane distillation desalination,” J. Membr. Sci., 2017, 539 458-474 (“Deshmukh 2017”).

Dongare, P. D., et al., “Nanophotonics-enabled solar membrane distillation for off-grid water purification,” Proc. Natl Acad. Sci. USA 2017, 114 6936-6941 (“Dongare 2017”),

Du, D., et al., “Effects of chloride and oxygen on stress corrosion cracking of cold worked 316/316L austenitic stainless steel in high temperature water,” Corrosion Sci., 2016, 110, 134-142 (“Du 2016”).

Dudchenko, A. V, et al., “Frequency-dependent stability of CNT Joule heaters in ionizable media and desalination processes,” Nat. Nanotechnol., 2017, 12, 557-563 (“Dudchenko 2017”).

Dwivedi, D., et al., “Carbon steel corrosion: a review of key surface properties and characterization methods, RSC Adv., 2017, 7, 4580-4610 (”Dwivedi 2017″).

Efome, E et al., “Enhanced performance of PVDF nanocomposite membrane by nanofiber coating: a membrane for sustainable desalination through MD,” Water Res., 2016, 89,39-49 (“Efome 2016”).

Elimelech, M., et al., “The future of seawater desalination: energy, technology, and the environment,” Science, 2011, 333, 712-717 (“Elimelech 2011”).

Falin, A., et al., “Mechanical properties of atomically thin boron nitride and the role of interlayer interactions,” Nat. Commun., 2017, 8,15815 (“Falin 2017”).

Finšgar, M, et al., “Application of corrosion inhibitors for steels in acidic media for the oil and gas industry: a review,” Corrosion Sci., 2017, 86, 17-41 (“Finšgar 2014”).

Fu, F., et al., “Direct growth of MoS2/h-BN heterostructures via a sulfide-resistant alloy,” ACS Nano, 2016, 10, 2063-2070 (“Fu 2016”).

Greenlee, L. F., et al., “Reverse osmosis desalination: water sources, technology, and today's challenges,” Water Res., 2009, 43, 2317-2348 (“Greenlee 2009”).

Hattori, Y et al., “Layer-by-layer dielectric breakdown of hexagonal boron nitride,” ACS Nano, 2015, 9, 916-921 (“Hattori 2015”).

Hao, Y, et al., “The role of surface oxygen in the growth of large single-crystal graphene on copper,” Science, 2013, 342, 720-724 (“Hao 2013”).

Ho, Y. S., et al., “Pseudo-second order model for sorption processes,” Process Biochem., 34, 451-465 (“Ho 1999”).

Hu S., et al., “Proton transport through one-atom-thick crystals,” Nature, 2014, 516, 227-230 (“Hu 20/4”).

Husain, E., et al., “Marine corrosion protective coatings of hexagonal boron nitride thin films on stainless steel,” ACS Appl. Mater. Interfaces, 2013, 5, 4129-4135 (“Husain 2013”).

Jia, S., et al., “CVD growth of high-quality and large-area continuous h-BN thin films directly on stainless-steel as protective coatings,” Materials Today Nano, 2021, 16, 100135 (first available on-line on Jul. 29, 2021) (“Jia 2021”).

Jia, S., et al., “Supplemental Information: CVD growth of high-quality and large-area continuous h-BN thin films directly on stainless-steel as protective coatings,” Materials Today Nano, 2021, 16, 100135 (first available on-line on Jul. 29, 2021) (“Jia 2021 Supplemental Information”).

Jia, S., et al., “Graphene oxide/graphene vertical heterostructure electrodes for highly efficient and flexible organic light emitting diodes,” Nanoscale, 2016, 8, 10714-10723 (“Jia 2016”).

Jiang, P., et al., “Anisotropic thermal transport in bulk hexagonal boron nitride,” Phys. Rev. Mater, 2018, 2, 064005 (“Jiang 2018”)

Kang, K., et al., “High-mobility three-atom-thick semiconducting films with wafer-scale homogeneity,” Nature, 2015, 520, 656-660 (“Kang 2015”).

Kim, K. K., et al., “Synthesis and characterization of hexagonal boron nitride film as a dielectric layer for graphene devices,” ACS Nano, 2012, 6, 8583-8590 (“Kim 2012”).

Kim, S. M., et al., “Synthesis of large-area multilayer hexagonal boron nitride for high material performance,” Nat. Commun., 2015, 6, 8662 (“Kim 2015”).

Kostoglou, N., et al., “Thermal and chemical stability of hexagonal boron nitride (h-BN) nanoplatelets,” Vacuum, 2015, 112, 42-45 (“Kostoglou 2015”).

Kuang, W. et al., “The oxidation behaviour of 304 stainless steel in oxygenated high temperature water,” Corrosion Sci., 2010, 52, 4081-4087 (“Kuang 2010”).

Lawson, K. W., et al., “Membrane distillation,” J. Membr. Sci., 1997, 124, 1-25 (“Lawson 1997”).

Lei, W., et al., “Porous boron nitride nanosheets for effective water cleaning,” Nat. Commun., 2013, 4, 1777 (“Lei 2013”).

Leitch, M. E. et al., “Bacterial nanocellulose aerogel membranes: novel high-porosity materials for membrane distillation,” Environ. Sci. Technol. Lett., 2016, 3, 85-91 (“Leitch 2016”).

Li, L. H., et al., “Boron nitride nanosheets for metal protection,” Adv. Mater. Interfac., 2014, 1, 1-6 (“Li 2014”).

Lin, S., et al., “Direct contact membrane distillation with heat recovery: thermodynamic insights from module scale modeling,” J. Membr. Sci., 2014, 453, 498-515 (“Lin 2014”).

Liu, Z., et al., “In-plane heterostructures of graphene and hexagonal boron nitride with controlled domain sizes,” Nat. Nanotechnol., 2013, 8, 119-124 (“Liu I 2013”).

Liu, Z., et al., “Ultrathin higherature oxidation-resistant coatings of hexagonal boron nitride,” Nat. Commun., 2013, 4, 1-8 (“Liu II 2013”).

Lu, G., et al., “Synthesis of high-quality graphene and hexagonal boron nitride monolayer in-plane heterostructure on Cu—Ni alloy,” Adv. Sci., 2017, 4, 1-7 (“Lu 2017”).

Lu, G., et al., “Synthesis of large single-crystal hexagonal boron nitride grains on Cu—Ni alloy,” Nat. Commun., 2015, 6, 6160 (“Lu 2015”).

Luo, W. H., et al., “An osmotic membrane bioreactor-membrane distillation system for simultaneous wastewater reuse and seawater desalination: performance and implications,” Environ. Sci. Technol., 2017, 51, 14311-14320 (“Luo 2017”).

Mahvash, F., et al., “Corrosion resistance of monolayer hexagonal boron nitride on copper,” Sci. Rep., 2017, 7, 1-5 (“Mahvash 2017”).

Mericq, J. P., el at, “Vacuum membrane distillation of seawater reverse osmosis brines,” Water Res., 2010, 44, 5260-5273 (“Mericq 2010”).

Naidu, G., et al., “Membrane distillation for wastewater reverse osmosis concentrate treatment with water reuse potential,” J. Membr. Sci., 2017, 524, 565-575 (“Naidu 2017”).

Najmaei, S., et al., “Vapour phase growth and grain boundary structure of molybdenum disulphide atomic layers,” Nat. Mater., 2013, 12, 754-759 (“Najmaei 2013”).

Pakdel, A., et al., “Low-dimensional boron nitride nanomaterials,” Materials Today, 2012, 15, 256-265 (“Pakdel 2012”).

Panossian, Z., et al., “Corrosion of carbon steel pipes and tanks by concentrated sulfuric acid: a review,” Corrosion Sci., 2011, 58, 1-11 (“Panossian 2012”).

Shaffer, D. L., et al., “Desalination and reuse of high-salinity shale gas produced water: drivers, technologies, and future directions. Environ,” Sci. Technol., 2013, 47, 9569-9583 (“Shaffer 2013”).

Song, L., et al., Large scale growth and characterization of atomic hexagonal boron nitride layers,” Nano Lett., 2010, 10, 3209-3215 (“Song 2010”).

Sun, J., et al., “Recent progress in the tailored growth of two-dimensional hexagonal boron nitride via chemical vapour deposition,” Chem. Soc. Rev., 2018, 47, 4242-4257 (“Sun 20./8”).

Tan, Y. Z., et al., “Localized induction heating of metallic spacers for energy-efficient membrane distillation,” J. Membr. Sci., 2020, 606, 118150 (“Tan 2020”).

Tang, S., et al., “Silane-catalysed fast growth of large single-crystalline graphene on hexagonal boron nitride,” Nat. Commun., 2015, 6, 649 (“Tang 2015”).

Tay, R. Y, et al., “Growth of large single-crystalline two-dimensional boron nitride hexagons on electropolished copper,” Nano Lett., 2014, 14, 839-846 (“Tay 2014”).

Tow, E. W., et al., “Comparison of fouling propensity between reverse osmosis, forward osmosis, and membrane distillation,” J. Membr. Sci., 2018, 556, 352-364 (“Tow 2018”).

Tran, T. T., et al., “Quantum emission from hexagonal boron nitride monolayers,” Nat. Nanotechnol., 2016, 11, 37-41 (“Tran 2016”).

Upadhyayula, V, et al., “Hexagonal boron nitride: the thinnest insulating barrier to microbial corrosion,” ACS Nano, 2018, 12, 2242-2252 (“Upadhyayula 2018”).

Walsh, F. C., et al., “The rotating cylinder electrode for studies of corrosion engineering and protection of metals—an illustrated review,” Corrosion Sci., 123, 1-20 (“Walsh 2017”).

Watanabe, K., et al, “Direct-bandgap properties and evidence for ultraviolet lasing of hexagonal boron nitride single crystal,” Nat. Mater., 2004, 3, 404-409 (“Watanabe 2004”).

Withers, F., et al., “Light-emitting diodes by band-structure engineering in van der Waals hetero structures,” Nat. Mater., 2015, 14, 301-306 (“Withers 2015”).

Yan, K., et al., “Ultrathin two-dimensional atomic crystals as stable interfacial layer for improvement of lithium metal anode,” Nano Lett., 2014, 14, 6016-6022 (“Yan 2014”).

Zanotto, F., et al., “Stress corrosion cracking of LDX 2101® duplex stainless steel in chloride solutions in the presence of thiosulphate,” Corrosion Sci., 2014, 80, 205-212 (“Zanotto 2014”).

Zhang, J., et al., “Investigation of hexagonal boron nitride as an atomically thin corrosion passivation coating in aqueous solution, Nanotechnology, 2016, 27, 364004 (”Zhang J 2016″).

Zhang, J., et al., “Janus monolayer transition-metal dichalcogenides,” ACS Nano, 2017, 11, 8192-8198 (“Zhang 2017”).

Zhang, Y., et al, “Review of thermal efficiency and heat recycling in membrane distillation processes,” Desalination, 2017, 367, 223-239 (“Zhang 2015”).

Zhang, Z., et al., “Growth mechanism and morphology of hexagonal boron stride,” Nano Lett., 2016, 16 1398-1403 (“Zhang Z 2016”).

Zuo, K., et al., “Multifunctional nanocoated membranes for high-rate electrothermal desalination of hypersaline waters,” Nat. Nanotechnol., 2020, 15, 1025-1032 (first available on-line on Oct. 26, 2020) (“Zuo 2020”).

Zuo, K., et al., “Supplementary Information: Multifunctional nanocoated membranes for high-rate electrothermal desalination of hypersaline waters,” 2020, 15, 1025-1032 (first available on-line Oct. 26, 2020) (“Zuo 2020 Supplemental Information”).

What is claimed is:

1. A method comprising:
(a) selecting substrate that is a ferrous metal or ferrous alloy substrate; and
(b) utilizing a low-pressure chemical vapor deposition to continuously grow a hexagonal boron nitride film upon the substrate to form a hexagonal boron nitride coated substrate.

2. The method of claim 1, wherein the substrate is a stainless steel substrate.

3. The method of claim 1, wherein the substrate is a microporous stainless steel wire cloth.

4. The method of claim 1, wherein the substrate is cleaned before the step of utilizing the low-pressure chemical vapor deposition.

5. The method of claim 4, wherein the substrate is cleaned to remove surface oxide.

6. The method of claim 1, wherein a precursor is utilized during the low-pressure chemical vapor deposition.

7. The method of claim 6, wherein the precursor is selected from the group consisting of (a) ammonia borane, (b) NH₃ and diborane, and (c) combinations thereof.

8. The method of claim 1, wherein a carrier gas is utilized during the low-pressure chemical vapor deposition.

9. The method of claim 8, wherein the carrier gas comprises a gas selected from the group consisting of hydrogen, Ar, He, and combinations thereof.

10. The method of claim 8, wherein the carrier gas is flowed during the low-pressure chemical vapor deposition at a rate in a range of 50 sccm and 500 sccm.

11. The method of claim 1, wherein the low-pressure chemical vapor deposition is performed at a pressure in a range of 0.01 Torr and 0.5 Torr.

12. The method of claim 1, wherein the method comprises utilizing a temperature of greater than 1,000° C. to grow the hexagonal boron nitride film.

13. The method of claim 1, wherein the method comprises ramping temperature from a first temperature below 1,000° C. to a second temperature of at least 1,000° C. over a first period of time.

14. The method of claim 13, wherein the method further comprises maintaining the temperature at the second temperature for a second period of time to grow the hexagonal boron nitride film.

15. The method of claim 14, wherein the method further comprising cooling the temperature to a third temperature below 1,000° C.

16. The method of claim 15, wherein the first temperature and the third temperature are room temperature.

17. The method of claim 1, wherein the hexagonal boron nitride film has a thickness less than 500 nm.

18. A coated substrate comprising:
(a) a substrate comprising ferrous metal or ferrous alloy substrate; and
(b) a continuous hexagonal boron nitride film coating the substrate.

19. The coated substrate of claim 18, wherein the substrate is a microporous stainless steel wire cloth.

20. A method comprising:
(a) selecting a coated substrate, wherein the coated substrate comprises
(i) a substrate comprising ferrous metal or ferrous alloy substrate, and
(ii) a continuous hexagonal boron nitride film coating the substrate; and
(b) utilizing the coated substrate as a surface electro-heating element of an electrothermal membrane distillation system.
